(19) United States
(12) Patent Application Publication
(10) Pub. No.: US 2026/0212822 A1
(43) Pub. Date: Jul. 23, 2026

(54) PIXEL, DISPLAY DEVICE, AND ELECTRONIC DEVICE

(71) Applicant: Samsung Display Co., LTD., Yongin-si (KR)

(72) Inventors: Boyong CHUNG, Yongin-si (KR); Bogyeong KIM, Yongin-si (KR); Jonghee KIM, Yongin-si (KR); Hyuk KIM, Yongin-si (KR); Byungseok CHOI, Yongin-si (KR)

(21) Appl. No.: 19/446,518

(22) Filed: Jan. 12, 2026

(30) Foreign Application Priority Data
Jan. 17, 2025 (KR) 10-2025-0007542

(51) Int. Cl. G09G 3/3233

(52) U.S. Cl. CPC G09G 3/3233; G09G 2300/043; G09G 2300/0819; G09G 2320/0242; G09G 2330/021

(57) ABSTRACT

A pixel includes a first transistor, a second transistor connected to a data line and including a gate connected to a scan line, a third transistor connected to the second transistor and a first node to which a gate of the first transistor is connected, a fourth transistor connected to the data line and a second node, a fifth transistor connected to the first node and the second node, a sixth transistor connected to a third node to which a second terminal of the first transistor is connected, wherein the sixth transistor is connected to a light-emitting element, a seventh transistor connected to the sixth transistor and an initialization voltage line, a first capacitor connected to the second node and the third node, and a second capacitor connected to the initialization voltage line and further to a fourth node to which the second transistor and the third transistor are connected.

This application claims priority to Korean Patent Application No. 10-2025-0007542, filed on January 17, 2025, and all the benefits accruing therefrom under 35 U.S.C. §119, the content of which in its entirety is herein incorporated by reference.

### BACKGROUND

### Field

One or more embodiments relate to a pixel, a display device including a pixel, and an electronic device.

### Description of the Related Art

Recently, the usage of display devices has diversified. In addition, as display devices have become thinner and lighter, their range of use has gradually been extended.

As a display device is variously utilized, there may be various methods of designing the shape of a display device, and also, the number of functions that may be combined or associated with a display device has increased.

### SUMMARY

One or more embodiments include a display device with high resolution. However, such an objective is just an example, and the disclosure is not limited thereto.

Additional aspects will be set forth in part in the description which follows and, in part, will be apparent from the description, or may be learned by practice of the presented embodiments of the disclosure.

According to one or more embodiments, a pixel includes a first transistor including a gate, a first terminal connected to a driving voltage line, and a second terminal, a second transistor connected to a data line and including a gate connected to a scan line, a third transistor connected to the second transistor and a first node to which the gate of the first transistor is connected, wherein the third transistor includes a gate connected to a first gate line, a fourth transistor connected to the data line and a second node and including a gate connected to a second gate line, a fifth transistor connected to the first node and the second node and including a gate connected to a third gate line, a sixth transistor connected to a third node to which the second terminal of the first transistor is connected and a light-emitting element, wherein the sixth transistor includes a gate connected to a fourth gate line, a seventh transistor connected to the sixth transistor and an initialization voltage line and including a gate connected to a fifth gate line, a first capacitor connected to the second node and the third node, and a second capacitor connected to a fourth node to which the second transistor and the third transistor are connected and the initialization voltage line.

In an embodiment, a first terminal of the seventh transistor may be connected to a fifth node, and a second terminal of the seventh transistor may be connected to the initialization voltage line, wherein the sixth transistor and a pixel electrode of the light-emitting element are connected to the fifth node, wherein a first gate signal may be input to the first gate line, wherein a second gate signal may be input to the second gate line and the fifth gate line, and wherein a third gate signal may be input to the third gate line and the fourth gate line.

In an embodiment, during a first period of a frame, the first gate signal and a scan signal which is input via the scan line may have a gate-off voltage, the second gate signal and the third gate signal may have a gate-on voltage, the gate of the first transistor may be initialized to a first voltage which is input to the data line, and the pixel electrode of the light-emitting element may be initialized to an initialization voltage which is input to the initialization voltage line.

In an embodiment, during a second period subsequent to the first period of the frame, the first gate signal and the second gate signal may have a gate-on voltage, the scan signal and the third gate signal may have a gate-off voltage, a data voltage stored in the second capacitor may be provided to the gate of the first transistor, and a second voltage which is input to the data line may be provided to the second node.

In an embodiment, during a third period subsequent to the second period of the frame, the first gate signal and the second gate signal may have a gate-off voltage, the third gate signal may have a gate-on voltage, the light-emitting element may emit light corresponding to a data voltage provided to the gate of the first transistor, and during a portion of the third period, the scan signal may have a gate-on voltage, and a data voltage which is associated with a next frame and input to the data line may be provided to the fourth node.

In an embodiment, a first terminal of the seventh transistor may be connected to the third node, and a second terminal of the seventh transistor may be connected to the initialization voltage line, wherein a first gate signal may be input to the first gate line, wherein a second gate signal may be input to the fifth gate line, wherein a third gate signal may be input to the third gate line and the fourth gate line, and wherein a fourth gate signal may be input to the second gate line.

In an embodiment, during a first period of a frame, the first gate signal and the scan signal may have a gate-off voltage, the second gate signal, the third gate signal, and the fourth gate signal may have a gate-on voltage, the gate of the first transistor may be initialized to a first voltage which is input to the data line, and a pixel electrode of the light-emitting element may be initialized to an initialization voltage which is input to the initialization voltage line.

In an embodiment, during a second period subsequent to the first period of the frame, the first gate signal and the fourth gate signal may have a gate-on voltage, the scan signal, the second gate signal, and the third gate signal may have a gate-off voltage, a data voltage stored in the second capacitor may be provided to the gate of the first transistor, and a second voltage which is input to the data line may be provided to the second node.

In an embodiment, during a third period subsequent to the second period of the frame, the first gate signal, the second gate signal, and the fourth gate signal may have a gate-off voltage, the third gate signal may have a gate-on voltage, the light-emitting element may emit light corresponding to a data voltage provided to the gate of the first transistor, and during a portion of the third period, the scan signal may have a gate-on voltage, and a data voltage which is associated with a next frame and input to the data line may be provided to the fourth node.

In an embodiment, a first terminal of the seventh transistor may be connected to a fifth node, and a second terminal of the seventh transistor may be connected to the initialization voltage line, wherein the sixth transistor and a pixel electrode of the light-emitting element are connected to the fifth node, wherein a first gate signal may be input to the first gate line, wherein a second gate signal may be input to the second gate line and the fifth gate line, wherein a third gate signal may be input to the third gate line, and wherein a fourth gate signal may be input to the fourth gate line.

In an embodiment, during a first period of a frame, the first gate signal and a scan signal which is input via the scan line may have a gate-off voltage, the second gate signal, the third gate signal, and the fourth gate signal may have a gate-on voltage, the gate of the first transistor may be initialized to a first voltage which is input to the data line, and a pixel electrode of the light-emitting element may be initialized to an initialization voltage which is input to the initialization voltage line.

In an embodiment, during a second period subsequent to the first period of the frame, the first gate signal and the second gate signal may have a gate-on voltage, the scan signal, the third gate signal, and the fourth gate signal may have a gate-off voltage, a data voltage stored in the second capacitor may be provided to the gate of the first transistor, and a second voltage which is input to the data line may be provided to the second node.

In an embodiment, during a third period subsequent to the second period of the frame, the first gate signal and the second gate signal may have a gate-off voltage, the third gate signal and the fourth gate signal may have a gate-on voltage, the light-emitting element may emit light corresponding to a data voltage provided to the gate of the first transistor, and during a portion of the third period, the scan signal may have a gate-on voltage, and a data voltage which is associated with a next frame and input to the data line may be provided to the fourth node.

According to one or more embodiments, a display device includes a controller which receives an on-operation signal from a processor and outputs a control signal based on the on-operation signal, a driving circuit which receives the control signal and includes a plurality of stages that sequentially output scan signals, at least one gate signal supply line which receives the control signal and outputs at least one gate signal, and a plurality of pixels, wherein each of the plurality of pixels includes a first transistor including a gate, a first terminal connected to a driving voltage line, and a second terminal, a second transistor connected to a data line and including a gate connected to a scan line to which a scan signal of the scan signals output by the driving circuit is input, a third transistor connected to the second transistor and a first node to which the gate of the first transistor is connected, wherein the third transistor includes a gate connected to a first gate line, a fourth transistor connected to the data line and a second node and including a gate connected to a second gate line, a fifth transistor connected to the first node and the second node and including a gate connected to a third gate line, a sixth transistor connected to a third node to which the second terminal of the first transistor is connected and a light-emitting element, wherein the sixth transistor includes a gate connected to a fourth gate line, a seventh transistor connected to the sixth transistor and an initialization voltage line and including a gate connected to a fifth gate line, a first capacitor connected to the second node and the third node, and a second capacitor connected to a fourth node to which the second transistor and the third transistor are connected and the initialization voltage line, and wherein the at least one gate signal supply line supplies a gate signal to each of the first gate line, the second gate line, the third gate line, the fourth gate line, and the fifth gate line.

In an embodiment, a first terminal of the seventh transistor may be connected to a fifth node to which the sixth transistor and a pixel electrode of the light-emitting element are connected, a second terminal of the seventh transistor may be connected to the initialization voltage line, wherein a first gate signal may be input to the first gate line, wherein a second gate signal may be input to the second gate line and the fifth gate line, and wherein a third gate signal may be input to the third gate line and the fourth gate line.

In an embodiment, during a first period of a frame, the first gate signal and the scan signal may have a gate-off voltage, the second gate signal and the third gate signal may have a gate-on voltage, the gate of the first transistor may be initialized to a first voltage which is input to the data line, and a pixel electrode of the light-emitting element may be initialized to an initialization voltage which is input to the initialization voltage line, wherein, during a second period subsequent to the first period of the frame, the first gate signal and the second gate signal may have a gate-on voltage, the scan signal and the third gate signal may have a gate-off voltage, a data voltage stored in the second capacitor may be provided to the gate of the first transistor, and a second voltage which is input to the data line may be provided to the second node, and wherein, during a third period subsequent to the second period of the frame, the first gate signal and the second gate signal may have a gate-off voltage, the third gate signal may have a gate-on voltage, and the light-emitting element may emit light at brightness corresponding to the data voltage provided to the gate of the first transistor, wherein during a portion of the third period, the scan signal may have a gate-on voltage, and a data voltage which is associated with a next frame and input to the data line may be provided to the fourth node.

In an embodiment, a first terminal of the seventh transistor may be connected to the third node, and a second terminal of the seventh transistor may be connected to the initialization voltage line, wherein a first gate signal may be input to the first gate line, wherein a second gate signal may be input to the fifth gate line, wherein a third gate signal may be input to the third gate line and the fourth gate line, and wherein a fourth gate signal may be input to the second gate line.

In an embodiment, during a first period of a frame, the first gate signal and the scan signal may have a gate-off voltage, the second gate signal, the third gate signal, and the fourth gate signal may have a gate-on voltage, the gate of the first transistor may be initialized to a first voltage which is input to the data line, and a pixel electrode of the light-emitting element may be initialized to an initialization voltage which is input to the initialization voltage line, wherein, during a second period subsequent to the first period of the frame, the first gate signal, and the fourth gate signal may have a gate-on voltage, the scan signal, the second gate signal, and the third gate signal may have a gate-off voltage, a data voltage stored in the second capacitor may be provided to the gate of the first transistor, and a second voltage which is input to the data line may be provided to the second node, and wherein, during a third period subsequent to the second period of the frame, the first gate signal, the second gate signal, and the fourth gate signal may have a gate-off voltage, the third gate signal may have a gate-on voltage, and the light-emitting element may emit light at brightness corresponding to the data voltage provided to the gate of the first transistor, wherein during a portion of the third period, the scan signal may have a gate-on voltage, and a data voltage which is associated with a next frame and input to the data line may be provided to the fourth node.

In an embodiment, a first terminal of the seventh transistor may be connected to a fifth node, and a second terminal of the seventh transistor may be connected to the initialization voltage line, wherein the sixth transistor and a pixel electrode of the light-emitting element are connected to the fifth node, wherein a first gate signal may be input to the first gate line, wherein a second gate signal may be input to the second gate line and the fifth gate line, wherein a third gate signal may be input to the third gate line, and wherein a fourth gate signal may be input to the fourth gate line.

In an embodiment, during a first period of a frame, the first gate signal and the scan signal may have a gate-off voltage, the second gate signal, the third gate signal, and the fourth gate signal may have a gate-on voltage, the gate of the first transistor may be initialized to a first voltage which is input to the data line, and a pixel electrode of the light-emitting element may be initialized to an initialization voltage which is input to the initialization voltage line, wherein, during a second period subsequent to the first period of the frame, the first gate signal and the second gate signal may have a gate-on voltage, the scan signal, the third gate signal, and the fourth gate signal may have a gate-off voltage, a data voltage stored in the second capacitor may be provided to the gate of the first transistor, and a second voltage which is input to the data line may be provided to the second node, and wherein, during a third period subsequent to the second period of the frame, the first gate signal and the second gate signal may have a gate-off voltage, the third gate signal and the fourth gate signal may have a gate-on voltage, and the light-emitting element may emit light at brightness corresponding to the data voltage provided to the gate of the first transistor, wherein during a portion of the third period, the scan signal may have a gate-on voltage, and a data voltage which is associated with a next frame and input to the data line may be provided to the fourth node.

An electronic device according to an embodiment may include the display device described herein.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic views of the display device according to an embodiment;

FIG. 3 is an equivalent circuit diagram of a pixel according to an embodiment;

FIG. 4 is a schematic view of signals for explaining an operation of the pixel illustrated in FIG. 3;

FIG. 5 is an enlarged plan view of a portion of a display device according to an embodiment, illustrating a region A of FIG. 1;

FIG. 6 is an equivalent circuit diagram of a pixel according to an embodiment;

FIG. 7 is a schematic view of signals for explaining an operation of the pixel illustrated in FIG. 6;

FIG. 8 is an enlarged plan view of a portion of a display device according to an embodiment, illustrating the region A of FIG. 1;

FIG. 9 is an equivalent circuit diagram of a pixel according to an embodiment;

FIG. 10 is a schematic view of signals for explaining an operation of the pixel illustrated in FIG. 9;

FIG. 11 is an enlarged plan view of a portion of a display device according to an embodiment, illustrating the region A of FIG. 1;

FIGS. 12A to 12D and FIGS. 13A and 13B are cross-sectional views of a structure of a display element according to an embodiment;

FIG. 14 is a schematic cross-sectional view of a structure of a display element according to an embodiment;

FIG. 15 is a block diagram of an electronic device according to an embodiment; and

FIG. 16 is a schematic view of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term "and/or" includes any and all combinations of one or more of the associated listed items. Throughout the disclosure, the expression "at least one of a, b, and c" indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described herein in detail with reference to the drawings. However, the disclosure is not limited to the following embodiments and may be embodied in various forms.

While such terms as "first" and "second" may be used to describe various elements, such elements must not be limited to the above terms. The above terms are used to distinguish one element from another.

The singular forms "a," "an," and "the" as used herein are intended to include the plural forms as well unless the context clearly indicates otherwise.

It will be understood that the terms "comprise," "comprising," "include" and/or "including" as used herein specify the presence of stated features or elements but do not preclude the addition of one or more other features or elements.

It will be further understood that, when a layer, region, or element is referred to as being "on" another portion, it can be directly or indirectly on the other portion. That is, for example, intervening layers, regions, or elements may be present.

In the present specification, "A and/or B" means A or B, or A and B. In the present specification, "at least one of A and B" means A or B, or A and B.

In embodiments below, when it is described that X is connected to Y, X may be electrically connected to Y, X may be functionally connected to Y, or X may be physically connected to Y. Here, X and Y may be objects (e.g., apparatuses, elements, circuits, wirings, electrodes, terminals, conductive layers, layers, and the like). Accordingly, X and Y are not limited to preset connection relationships and connection relationships illustrated and made in the drawings and the detailed description, but may include connection relationships other than the connection relationships illustrated and made in the drawings and the detailed description.

The case where X is electrically connected to Y may include a case where X is directly connected to Y and a case where at least one element (e.g., a switch, a transistor, a capacitance element, an inductor, a resistance element, a diode, and the like) enabling electrical connection between X and Y is connected between X and Y.

In embodiments below, "ON" used in association with an element state may denote an active state of an element, and "OFF" may denote an inactive state of an element. "ON" used in association with a signal received by an element may denote a signal activating the element, and "OFF" may denote a signal inactivating the element. An element may be activated by a high-level voltage or a low-level voltage. As an example, a P-channel transistor (a P-type transistor) may be activated by a low-level voltage, and an N-channel transistor (an N-type transistor) may be activated by a high-level voltage. Accordingly, it should be understood that "ON" voltages for a P-type transistor and an N-type transistor are opposite (low vs. high) voltage levels.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

An x direction, a y direction, and a z direction are not limited to directions along three axes of the rectangular coordinate system, and may be interpreted in a broader sense. For example, the x direction, the y direction, and the z direction may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

Sizes of elements in the drawings may be exaggerated or reduced for convenience of explanation. As an example, the size and thickness of each element illustrated in the drawings are arbitrarily represented for convenience of description, and thus, the disclosure is not necessarily limited thereto.

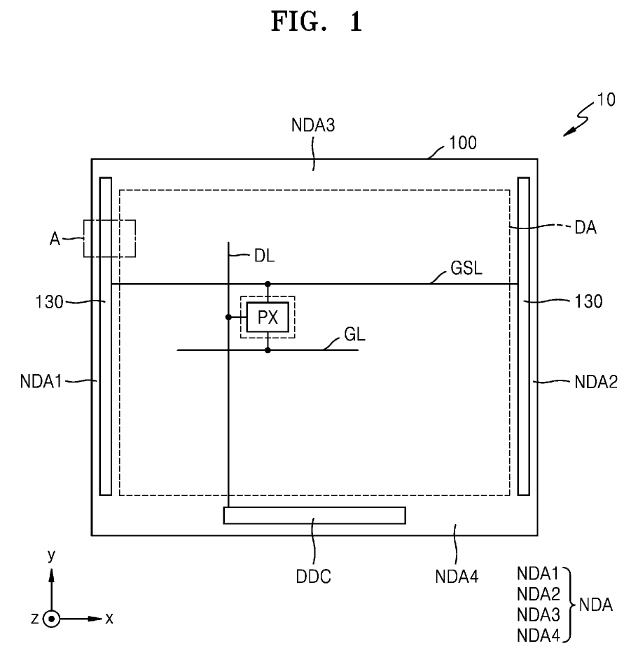

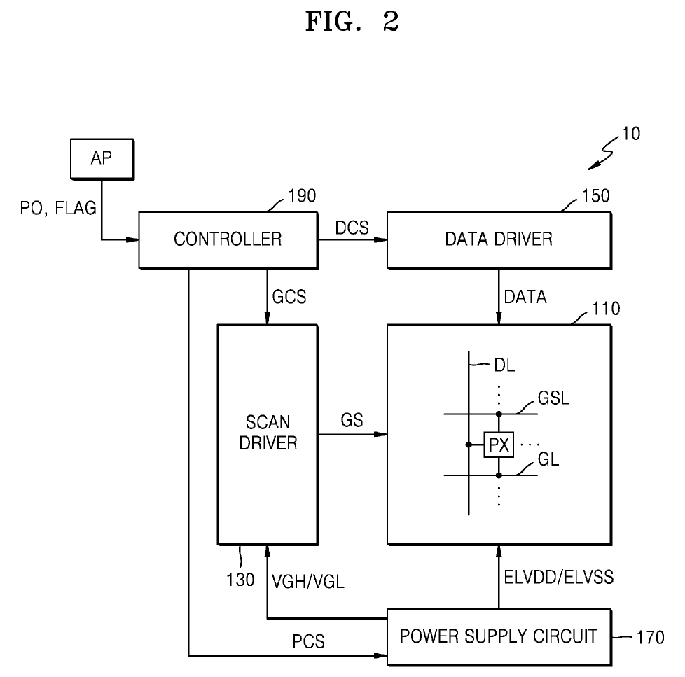

FIGS. 1 and 2 are schematic views of a display device 10 according to an embodiment.

The display device 10 displays moving images or still images and provides a user with visual information. The display device 10 according to an embodiment may be an organic light-emitting display device, an inorganic light-emitting display device, or a quantum-dot light-emitting display device.

Referring to FIGS. 1 and 2, the display device 10 may include a display area DA and a non-display area NDA. The display device 10 may include a display panel 110.

The display panel 110 may include a liquid crystal display panel, an organic light-emitting display panel, or an inorganic light-emitting display panel, and the type of display panel 110 is not particularly limited. The display panel 110 may be a rigid type, a flexible type that is rollable or foldable, or a stretchable type that is stretchable.

The display panel 110 may include a substrate 100, and a plurality of scan lines GSL, a plurality of data lines DL, a plurality of gate lines GL, and a plurality of pixels PX connected thereto may be arranged in the display area DA of the substrate 100.

The plurality of pixels PX may be repeatedly arranged in a first direction (an x direction, a row direction) and a second direction (a y direction, a column direction). The plurality of pixels PX may be arranged in various configurations such as, for example, a stripe configuration, a pentile configuration, a diamond configuration, a mosaic configuration, and the like to display images. Each of the plurality of pixels PX may include an organic light-emitting diode as a display element. The organic light-emitting diode may be connected to a pixel circuit. The pixel circuit may include a plurality of transistors and at least one capacitor. The pixel PX may be configured to emit, for example, red, green, blue, or white light through an organic light-emitting diode OLED. Each pixel PX may be connected to a corresponding scan line among the plurality of scan lines GSL and a corresponding data line among the plurality of data lines DL.

The scan lines GSL may each extend in the x direction (a row direction) and be connected to the pixels PX arranged in the same row. The scan lines GSL may each be configured to provide scan signals GS to the pixels PX in the same row. The data lines DL may each extend in the y direction (a column direction) and be connected to the pixels PX arranged in the same column. The data lines DL may be configured to respectively provide image data signals DATA to the pixels PX in the same column in synchronization with scan signals. The gate lines GL may each extend in the x direction (a row direction) and be connected to the pixels PX arranged in the same row. The gate lines GL may each be configured to provide gate signals to the pixels PX.

Various conductive lines configured to provide electrical signals to be applied to the display area DA, outer circuits electrically connected to pixel circuits, and pads to which a printed circuit board or a driver integrated circuit (IC) chip is attached may be located in the non-display area NDA outside the display area DA. As an example, a scan driver 130, a data driver 150, a power supply circuit 170, and a controller 190 may be provided in the non-display area NDA.

The scan driver 130 may be connected to the plurality of scan lines GSL, configured to generate scan signals GS in response to scan driving control signals GCS from the controller 190, and sequentially supply the scan signals GS to the scan lines GSL. The scan lines GSL may be connected to a gate of one of the transistors included in the pixel PX, and a scan signal GS may be a gate control signal that controls turn-on and turn-off of the transistor to which the scan line GSL is connected. A scan signal GS may include a gate-on voltage by which a transistor may be turned on, and a gate-off voltage by which a transistor may be turned off. The scan driver 130 may include a plurality of stages configured to sequentially generate and output scan signals GS.

The data driver 150 may be connected to the plurality of data lines DL and configured to supply image data signals DATA to the data lines DL in response to data driving control signals DCS from the controller 190. The image data signals DATA input to the data lines DL may be input to the pixels PX to which scan signals are input. The data driver 150 may be configured to convert input image data into an image data signal DATA of a voltage or current form, wherein the input image data has a grayscale and input from the controller 190. In an embodiment, the data driving control signal DCS may include a start signal and a plurality of clock signals.

In an embodiment, the data driver 150 may supply an off-voltage Voff and a reference voltage Vref to the data lines DL in response to a data driving control signal DCS. The data driver 150 may simultaneously supply off-voltages Voff and reference voltages Vref to all of the pixels in the display area DA. In an embodiment, the off-voltage Voff and the reference voltage Vref may be voltages transmitted (bypassed) through the data lines DL.

The power supply circuit 170 may be configured to generate signals (voltages and currents) which drive the pixels PX in response to a power driving control signal PCS from the controller 190.

In the case where the display device 10 is an organic light-emitting display device, the power supply circuit 170 may be configured to generate a first power voltage ELVDD and a second power voltage ELVSS and supply the same to the pixels PX. The first power voltage ELVDD may be a high-level voltage provided to one terminal of a driving transistor connected to a first electrode (a pixel electrode or an anode) of an organic light-emitting diode included in each pixel PX. The second power voltage ELVSS may be a low-level voltage provided to a second electrode (an opposite electrode or a cathode) of the organic light-emitting diode. The first power voltage ELVDD and the second power voltage ELVSS may be driving voltages configured to allow the plurality of pixels PX to emit light. In an embodiment, the power supply circuit 170 may be configured to supply clock signals, high-level voltage signals VGH, and low-level voltage signals VGL input to the scan driver 130.

The controller 190 may be configured to generate scan driving control signals GCS, data driving control signals DCS, and power driving control signals PCS based on signals input from the outside. The controller 190 may be configured to supply a scan driving control signal GCS to the scan driver 130, supply a data driving control signal DCS to the data driver 150, and supply a power driving control signal PCS to the power supply circuit 170.

In an embodiment, the display device 10 may be connected to a processor of an electronic device. The processor may include an application processor (AP). The controller 190 may receive an on-operation signal, for example, a power-on signal PO and/or an operation flag signal FLAG, from the application processor AP. In an example in which the electronic device is powered on or awakened from a sleep mode by a user, the controller 190 may receive an on-operation signal from the application processor AP and generate and output a scan driving control signal GCS, a data driving control signal DCS, and a power driving control signal PCS based on the on-operation signal.

Although the display device 10 of FIG. 2 includes the power supply circuit 170 and the controller 190 independently, embodiments of the present disclosure are not limited thereto. In an embodiment, the power supply circuit 170 may be included in the controller 190.

In an embodiment, the scan driver 130, the data driver 150, the power supply circuit 170, and the controller 190 are driving chips and may be mounted on the display panel 110. The data driver 150, the power supply circuit 170, and the controller 190 may be formed as separate integrated circuit chips, respectively, or one integrated circuit chip, and arranged on a flexible printed circuit board (FPCB) electrically connected to a pad arranged on one side of the substrate 100 forming the display panel 110. In another embodiment, the data driver 150, the power supply circuit 170, and the controller 190 may be directly arranged on the substrate using a chip-on-glass (COG) or chip-on-plastic (COP) method.

In an embodiment, a portion or all of the scan driver 130 may be directly formed in a peripheral area of the substrate during a process of forming a transistor configuring a pixel circuit in the display area of the substrate. The scan driver 130 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display panel 110.

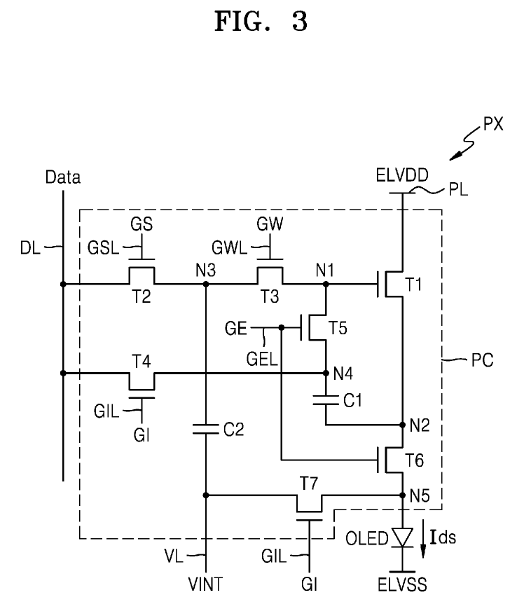

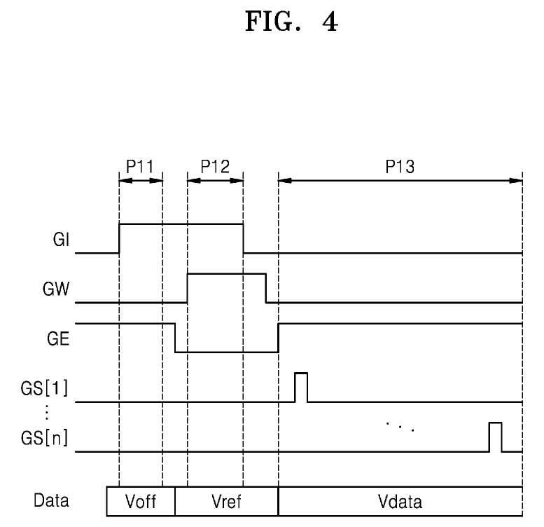

FIG. 3 is an equivalent circuit diagram of a pixel PX according to an embodiment. FIG. 4 is a schematic view of signals for explaining an operation of the pixel PX illustrated in FIG. 3.

Referring to FIG. 3, the pixel PX may include an organic light-emitting diode OLED as a display element, and a pixel circuit PC connected to the organic light-emitting diode OLED. The pixel circuit PC may include first to seventh transistors T1, T2, T3, T4, T5, T6, and T7, and first and second capacitors C1 and C2. The first transistor T1 may be a driving transistor configured to output a driving current corresponding to an image data signal DATA (FIG. 2), and the second to seventh transistors T2, T3, T4, T5, T6, and T7 may be switching transistors configured to provide signals. A first terminal (a first electrode) and a second terminal (a second electrode) of each of the first to the seventh transistors T1, T2, T3, T4, T5, T6, and T7 may be a source or a drain depending on the voltage of the first terminal and the second terminal. As an example, the first terminal may be a drain and the second terminal may be a source, or the first terminal may be a source and the second terminal may be a drain depending on the voltage of the first terminal and the second terminal.

In an embodiment, the plurality of transistors included in the pixel circuit may be N-channel transistors. A high-level voltage input to a gate of an N-channel transistor may be a gate-on voltage, and a low-level voltage may be defined as a gate-off voltage. An N-channel transistor may be an N-channel oxide transistor. An oxide transistor may include an oxide semiconductor, and the oxide semiconductor is a Zn-oxide-based material and may include a Zn oxide, an In-Zn oxide, a Ga-In-Zn oxide, and the like. In an embodiment, the oxide semiconductor may be an In-Ga-Zn-O (IGZO) semiconductor. In an embodiment, the oxide semiconductor may be an In-Sn-Ga-Zn-O (ITGZO) semiconductor. As an example, the oxide transistor may be a low temperature polycrystalline oxide silicon (LTPO) thin-film transistor.

The pixel PX may be connected to the scan line GSL via which a scan signal GS is provided, a first gate line GWL via which a first gate signal GW is provided, a second gate line GIL via which a second gate signal GI is provided, a third gate line GEL via which a third gate signal GE is provided, and the data line DL via which a data signal Data is provided. In some aspects, the pixel PX may be connected to a driving voltage line PL via which a first power voltage ELVDD is provided, and an initialization voltage line VL via which an initialization voltage VINT is provided. Referring to FIG. 4, the data signal Data may include the off-voltage Voff input to the data line DL during a first period P11, the reference voltage Vref input to the data line DL during a second period P12, and an image data signal DATA (referred to as a 'data voltage Vdata', hereinafter) in the form of a voltage input to the data line DL during a third period P13.

The first transistor T1 may be connected to the driving voltage line PL and a second node N2. The first transistor T1 may include a gate, a first terminal, and a second terminal, wherein the gate is connected to a first node N1, the first terminal is connected to the driving voltage line PL, and the second terminal is connected to the second node N2. The second terminal of the first transistor T1 may be connected to the organic light-emitting diode OLED through the sixth transistor T6. The first transistor T1 may output a driving current Ids corresponding to the data voltage Vdata.

The second transistor T2 may be connected to the data line DL and a third node N3. The second transistor T2 may include a gate, a first terminal, and a second terminal, wherein the gate is connected to the scan line GSL, the first terminal is connected to the data line DL, and the second terminal is connected to the third node N3. The second transistor T2 may be turned on according to a scan signal GS provided to the scan line GSL. In the state in which the second transistor T2 is turned on, the second transistor T2 may electrically connect the data line DL to the third node N3 and provide the data voltage Vdata provided to the data line DL to the third node N3.

The third transistor T3 may be connected to the third node N3 and the first node N1. The third transistor T3 may include a gate, a first terminal, and a second terminal, wherein the gate is connected to the first gate line GWL, the first terminal is connected to a second terminal of the second transistor T2, and the second terminal is connected to the gate of the first transistor T1. The third transistor T3 may be turned on according to a first gate signal GW provided to the first gate line GWL. In the state in which the third transistor T3 is turned on, the third transistor T3 may electrically connect the third node N3 to the first node N1 and provide a data voltage Vdata provided to the data line DL to the first node N1.

The fourth transistor T4 may be connected to the data line DL and a fourth node N4. The fourth transistor T4 may include a gate, a first terminal, and a second terminal, wherein the gate is connected to the second gate line GIL, the first terminal is connected to the data line DL, and the second terminal is connected to the fourth node N4. The fourth transistor T4 may be turned on according to a second gate signal GI provided to the second gate line GIL. In the state in which the fourth transistor T4 is turned on, the fourth transistor T4 may electrically connect the data line DL to the fourth node N4 and provide the off-voltage Voff and the reference voltage Vref provided to the data line DL to the fourth node N4.

The fifth transistor T5 may be connected to the first node N1 and the fourth node N4. The fifth transistor T5 may include a gate, a first terminal, and a second terminal, wherein the gate is connected to the third gate line GEL, the first terminal is connected to the gate of the first transistor T1, and the second terminal is connected to the fourth node N4. The fifth transistor T5 may be turned on or turned off according to a third gate signal GE provided to the third gate line GEL.

The sixth transistor T6 may be connected to the second node N2 and the organic light-emitting diode OLED. The sixth transistor T6 may include a gate, a first terminal, and a second terminal, wherein the gate is connected to the third gate line GEL, the first terminal is connected to the second terminal of the first transistor T1, and the second terminal is connected to a pixel electrode of the organic light-emitting diode OLED. The sixth transistor T6 may be turned on or turned off according to a third gate signal GE provided to the third gate line GEL.

The seventh transistor T7 may be connected to the organic light-emitting diode OLED and the initialization voltage line VL. The seventh transistor T7 may include a gate, a first terminal, and a second terminal, wherein the gate is connected to the second gate line GIL, the first terminal is connected to the pixel electrode of the organic light-emitting diode OLED, and the second terminal is connected to the initialization voltage line VL. The seventh transistor T7 may be turned on according to a second gate signal GI provided to the second gate line GIL and configured to provide the initialization voltage VINT provided to the initialization voltage line VL to the pixel electrode of the organic light-emitting diode OLED.

The first capacitor C1 may be connected to the fourth node N4 and the second node N2. A first terminal of the first capacitor C1 may be connected to the second terminal of the fourth transistor T4 and the second terminal of the fifth transistor T5. A second terminal of the first capacitor C1 may be connected to the second terminal of the first transistor T1 and the first terminal of the sixth transistor T6. The first capacitor C1 is a storage capacitor and configured to store a threshold voltage of the first transistor T1 and a voltage corresponding to a data voltage Vdata of a current frame.

The second capacitor C2 may be connected to the third node N3 and the initialization voltage line VL. A first terminal of the second capacitor C2 may be connected to the second terminal of the second transistor T2 and the first terminal of the third transistor T3. A second terminal of the second capacitor C2 may be connected to the second terminal of the seventh transistor T7 and the initialization voltage line VL. The second capacitor C2 may store the data voltage Vdata of a next frame provided through the second transistor T2 during an emission period.

The organic light-emitting diode OLED may be connected to the first transistor T1 through the sixth transistor T6. The organic light-emitting diode OLED may include the pixel electrode (an anode) and the opposite electrode (a cathode), wherein the pixel electrode is connected to the second terminal of the sixth transistor T6, and the opposite electrode faces the pixel electrode. The opposite electrode may receive the second power voltage ELVSS. The opposite electrode may be a common electrode that is common over the plurality of pixels PX.

Referring to FIG. 4, the first period P11 may be an initialization period during which the gate of the first transistor T1 and the pixel electrode of the organic light-emitting diode OLED are initialized. The second period P12 may be a compensation period in which the threshold voltage of the first transistor T1 is compensated. The third period P13 may be an emission period and a data-write period.

The first period P11 to the third period P13 are simultaneously applicable to all the pixels PX. During the first period P11, gates of the first transistors T1 and the pixel electrodes of the organic light-emitting diodes OLED of all the pixels PX may be initialized. During the second period P12, the threshold voltages of the first transistors T1 of all the pixels PX may be simultaneously compensated. During the third period P13, all the pixels PX may simultaneously emit light. During the third period P13, image data signals DATA (FIG. 2) may be sequentially input from the pixels PX in a first row to the pixels PX in a last row.

Hereinafter, driving of the pixel PX illustrated in FIG. 3 is described with reference to FIG. 4.

During the first period P11, the pixel PX may receive a second gate signal GI and a third gate signal GE of a gate-on voltage. During the first period P11, a scan signal GS and a first gate signal GW may have gate-off voltages. The off-voltage Voff may be supplied to the data line DL. The off-voltage Voff may be a voltage that allows the first transistor T1 to be turned off during the first period P11. In an embodiment, the off-voltage Voff may be a voltage equal to or less than the initialization voltage VINT.

The fourth transistor T4 and the seventh transistor T7 may be turned on according to a second gate signal GI, and the fifth transistor T5 and the sixth transistor T6 may be turned on according to a third gate signal GE. The first transistor T1, the second transistor T2, and the third transistor T3 may be turned off.

The off-voltage Voff supplied to the data line DL may be provided to the fourth node N4 and the first node N1 by the fourth transistor T4 and the fifth transistor T5 that are turned on. Accordingly, the gate of the first transistor T1 may be initialized to the off-voltage (or referred to as a first voltage) Voff.

The initialization voltage VINT may be provided to a fifth node N5 and the second node N2 by the seventh transistor T7 and the sixth transistor T6 that are turned on. Accordingly, a second terminal of the first transistor T1 and the pixel electrode of the organic light-emitting diode OLED may be initialized to the initialization voltage VINT.

During the second period P12, the pixel PX may receive a first gate signal GW and a second gate signal GI of a gate-on voltage. A scan signal GS and a third gate signal GE may be gate-off voltages. The reference voltage (or referred to as a second voltage) Vref may be supplied to the data line DL.

The third transistor T3 may be turned on by a first gate signal GW, and the fourth transistor T4 and the seventh transistor T7 may be turned on by a second gate signal GI. The second transistor T2, the fifth transistor T5, and the sixth transistor T6 may be turned off.

The data voltage Vdata of a current frame provided to the third node N3 during the third period P13 of a previous frame may be provided to the first node N1 by the third transistor T3 that is turned on. The first transistor T1 operates according to a source-follower operation due to the data voltage Vdata, and a voltage of the second terminal of the first transistor T1 may be a voltage (Vdata-Vth) obtained by subtracting a threshold voltage Vth of the first transistor T1 from the data voltage Vdata.

The reference voltage Vref supplied from the data line DL may be provided to the fourth node N4 by the fourth transistor T4 that is turned on. Accordingly, because a voltage difference (Vref-Vdata+Vth) between both terminals of the first capacitor C1 is stored in the first capacitor C1, the threshold voltage Vth of the first transistor T1 may be compensated.

A voltage of the fifth node N5 may maintain the initialization voltage VINT of the first period P11 due to the seventh transistor T7 that is turned on.

During the third period P13, the pixel PX may receive a third gate signal GE of a gate-on voltage. A first gate signal GW and a second gate signal GI may be gate-off voltages. The third transistor T3, the fourth transistor T4, and the seventh transistor T7 may be turned off.

The fifth transistor T5 and the sixth transistor T6 may be turned on by a third gate signal GE. The first transistor T1 may output the driving current Ids, which is a source-drain current determined according to a gate-source voltage Vgs, due to the fifth transistor T5 and the sixth transistor T6 that are turned on. Voltages of the second node N2 and the fifth node N5 may be a voltage Vel corresponding to the driving current Ids output by the first transistor T1. Voltages of the fourth node N4, which is the first terminal of the first capacitor C1, and the first node N1 may be a voltage (Vref-Vdata+Vth+Vel) changed in response to a change in the second node N2, which is the second terminal of the first capacitor C1.

The driving current Ids (Ids∝(Vgs-Vth)²=(Vref-Vdata+Vth-Vth)²=(Vref-Vdata)²) output by the first transistor T1 flows through the organic light-emitting diode OLED through the sixth transistor T6 that is turned on, and the organic light-emitting diode OLED may emit light at a brightness corresponding to the driving current Ids.

While all the pixels PX emit light during the third period P13, a first scan signal GS[1] to a last n-th scan signal GS[n] of a gate-on voltage is sequentially supplied to the display area DA, and the data voltage Vdata of a next frame may be sequentially written from the pixels PX in a first row to the pixels PX in a last n-th row. The second transistor T2 of a pixel to which a scan signal GS of a gate-on voltage is supplied, may be turned on. The data voltage Vdata of a next frame supplied to the data line DL is provided to the third node N3 by the second transistor T2 that is turned on, and the data voltage Vdata of the next frame may be stored in the second capacitor C2.

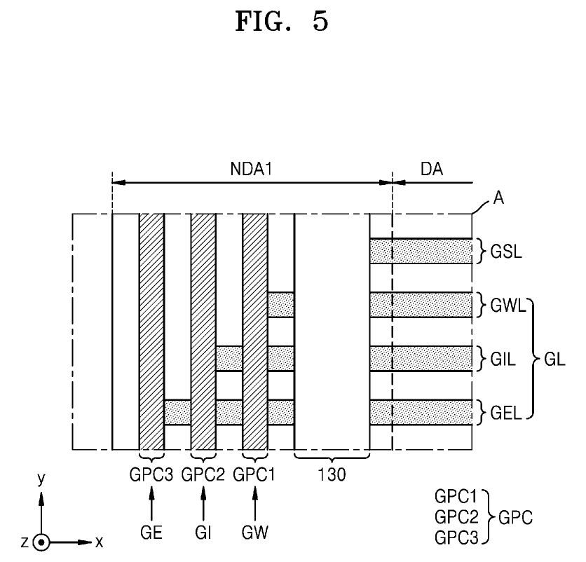

FIG. 5 is an enlarged plan view of a portion of the display device 10 according to an embodiment, illustrating a region A of FIG. 1.

Referring to FIG. 5, the display device 10 to which the pixel PX illustrated in FIG. 3 is applied may include gate signal supply lines GPC in the non-display area NDA. Although it is illustrated in FIG. 5 that the gate signal supply lines GPC are arranged outside the scan driver 130, embodiments of the present disclosure are not limited thereto. As an example, some of the gate signal supply lines GPC may overlap at least a portion of the scan driver 130.

In an embodiment, the gate signal supply lines GPC may be arranged in at least some of a first non-display area NDA1, a second non-display area NDA2, a third non-display area NDA3, and a fourth non-display area NDA4. As an example, at least one of the gate signal supply lines GPC may be successively arranged in the first non-display area NDA1, the second non-display area NDA2, and the third non-display area NDA3 along the edge of the display area DA. Alternatively, at least one of the gate signal supply lines GPC may be arranged in each of the first non-display area NDA1 and the second non-display area NDA2 along the edge of the display area DA.

The power supply circuit 170 may supply gate signals to the gate signal supply lines GPC. The gate signal supply lines GPC may include a first gate signal supply line GPC1 supplying a first gate signal GW, a second gate signal supply line GPC2 supplying a second gate signal GI, and a third gate signal supply line GPC3 supplying a third gate signal GE. The gate signal supply lines GPC may be connected to the gate lines GL in the display area DA.

The first gate signal supply line GPC1 may be connected to the first gate line GWL and may supply a first gate signal GW to the first gate line GWL. The second gate signal supply line GPC2 may be connected to the second gate line GIL and may supply a second gate signal GI to the second gate line GIL. The third gate signal supply line GPC3 may be connected to the third gate line GEL and may supply a third gate signal GE to the third gate line GEL.

In an embodiment, the first gate signal supply line GPC1, the second gate signal supply line GPC2, and the third gate signal supply line GPC3 may be arranged on the same layer, be arranged on different layers from each other, or some may be arranged on the same layer and the remaining others may be arranged on different layers from each other.

The thicknesses and arrangement positions of the first gate signal supply line GPC1, the second gate signal supply line GPC2, and the third gate signal supply line GPC3, and the thicknesses and arrangement positions of the first gate line GWL, the second gate line GIL, the third gate line GEL, and the scan lines GSL illustrated in FIG. 5 are just examples, and are not limited to those illustrated in FIG. 5 and may be variously modified.

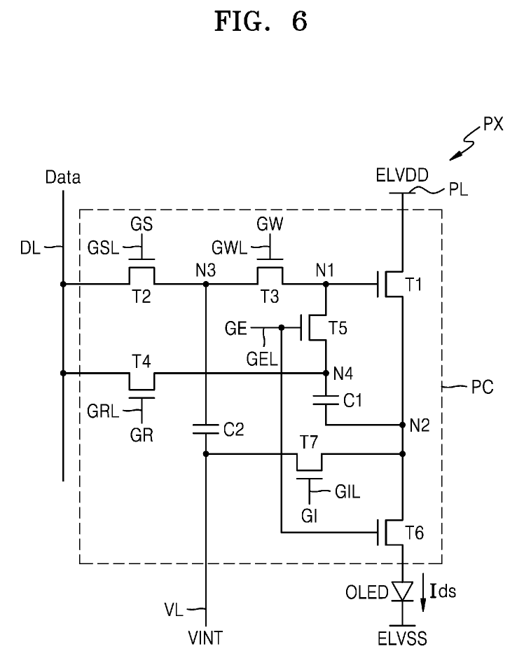

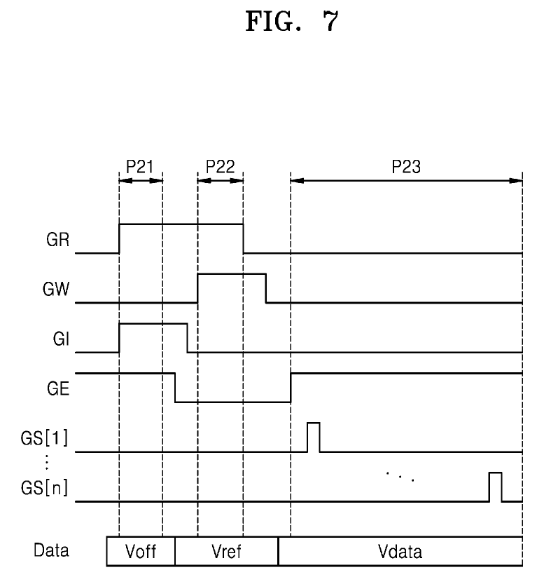

FIG. 6 is an equivalent circuit diagram of a pixel PX according to an embodiment. FIG. 7 is a schematic view of signals for explaining an operation of the pixel PX illustrated in FIG. 6.

The pixel PX illustrated in FIG. 6 is different from the pixel PX illustrated in FIG. 3 in that a gate of the fourth transistor T4 is connected to the fourth gate line GRL, and the seventh transistor T7 is connected to the second node N2. Hereinafter, the differences between FIG. 3 and FIG. 6 are mainly described, and descriptions of the same construction and operation are omitted.

The fourth transistor T4 may include a gate, a first terminal, and a second terminal, wherein the gate is connected to the fourth gate line GRL, the first terminal is connected to the data line DL, and the second terminal is connected to the fourth node N4. The fourth transistor T4 may be turned on according to a fourth gate signal GR input to the fourth gate line GRL. In the state in which the fourth transistor T4 is turned on, the fourth transistor T4 may electrically connect the data line DL to the fourth node N4 and provide the off-voltage Voff and the reference voltage Vref provided to the data line DL to the fourth node N4.

The seventh transistor T7 includes a gate, a first terminal, and a second terminal, wherein the gate is connected to the second gate line GIL, the first terminal is connected to the second node N2, and the second terminal is connected to the initialization voltage line VL. The seventh transistor T7 may be turned on according to a second gate signal GI provided to the second gate line GIL and configured to provide the initialization voltage VINT provided to the initialization voltage line VL to the second node N2.

Referring to FIG. 7, a first gate signal GW may be supplied as a gate-on voltage during a second period P22, and be supplied as a gate-off voltage during a first period P21 and a third period P23. A second gate signal GI may be supplied as a gate-on voltage during the first period P21, and be supplied as a gate-off voltage during the second period P22 and the third period P23. A third gate signal GE may be supplied as a gate-off voltage during the second period P22, and be supplied as a gate-on voltage during the first period P21 and the third period P23. A fourth gate signal GR may be supplied as a gate-on voltage during the first period P21 and the second period P22, and be supplied as a gate-off voltage during the third period P23.

During the first period P21, the seventh transistor T7 may be turned on by a second gate signal GI of a gate-on voltage, the fourth transistor T4 may be turned on by a fourth gate signal GR of a gate-on voltage, and the fifth transistor T5 and the sixth transistor T6 may be turned on by a third gate signal GE of a gate-on voltage.

The off-voltage Voff supplied to the data line DL may be provided to the fourth node N4 and the first node N1 by the fourth transistor T4 and the fifth transistor T5 that are turned on. Accordingly, the gate of the first transistor T1 may be initialized to the off-voltage Voff.

The initialization voltage VINT may be provided to the second node N2 and the pixel electrode of the organic light-emitting diode OLED by the seventh transistor T7 and the sixth transistor T6 that are turned on. Accordingly, the pixel electrode of the organic light-emitting diode OLED may be initialized to the initialization voltage VINT.

During the second period P22, the third transistor T3 may be turned on according to a first gate signal GW of a gate-on voltage, and the fourth transistor T4 may be turned on according to a fourth gate signal GR of a gate-on voltage.

The data voltage Vdata provided to the third node N3 during the third period P23 of a previous frame, may be provided to the first node N1 by the third transistor T3 that is turned on. The first transistor T1 is turned on, and a voltage of the second terminal of the first transistor T1 may be a voltage (Vdata-Vth) obtained by subtracting the threshold voltage Vth of the first transistor T1 from the data voltage Vdata. The reference voltage Vref supplied from the data line DL may be provided to the fourth node N4 by the fourth transistor T4 that is turned on. Accordingly, because a voltage difference (Vref-Vdata+Vth) between both terminals of the first capacitor C1 is stored in the first capacitor C1, the threshold voltage Vth of the first transistor T1 may be compensated.

During the third period P23, the fifth transistor T5 and the sixth transistor T6 are turned on according to a third gate signal GE of a gate-on voltage, and the first transistor T1 may output the driving current Ids determined by a gate-source voltage Vgs. The driving current Ids (Ids∝ (Vref-Vdata)²) output by the first transistor T1 flows through the organic light-emitting diode OLED through the sixth transistor T6 that is turned on, and the organic light-emitting diode OLED may emit light at a brightness corresponding to the driving current Ids.

While all the pixels PX emit light during the third period P23, a first scan signal GS[1] to a last n-th scan signal GS[n] of a gate-on voltage is sequentially supplied to the display area DA, and the data voltage Vdata of a next frame may be sequentially written from the pixels PX in a first row to the pixels PX in a last n-th row. The second transistor T2 of the pixel PX to which a scan signal GS of a gate-on voltage is supplied is turned on, the data voltage Vdata of a next frame supplied to the data line DL is provided to the third node N3, and the data voltage Vdata of the next frame may be stored in the second capacitor C2.

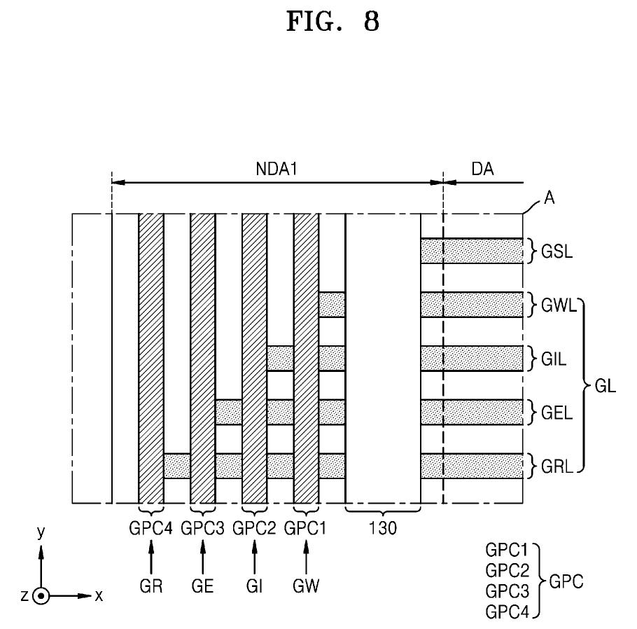

FIG. 8 is an enlarged plan view of a portion of the display device 10 according to an embodiment, illustrating the region A of FIG. 1.

Referring to FIG. 8, in an embodiment, the display device 10 to which the pixel PX illustrated in FIG. 6 is applied may include gate signal supply lines GPC in the non-display area NDA. The gate signal supply lines GPC may include a first gate signal supply line GPC1 supplying a first gate signal GW, a second gate signal supply line GPC2 supplying a second gate signal GI, a third gate signal supply line GPC3 supplying a third gate signal GE, and a fourth gate signal supply line GPC4 supplying a fourth gate signal GR.

The first gate signal supply line GPC1 is connected to the first gate line GWL and may supply a first gate signal GW supplied from the power supply circuit 170 to the first gate line GWL. The second gate signal supply line GPC2 is connected to the second gate line GIL and may supply a second gate signal GI supplied from the power supply circuit 170 to the second gate line GIL. The third gate signal supply line GPC3 is connected to the third gate line GEL and may supply a third gate signal GE supplied from the power supply circuit 170 to the third gate line GEL. The fourth gate signal supply line GPC4 is connected to the fourth gate line GRL and may supply a fourth gate signal GR supplied from the power supply circuit 170 to the fourth gate line GRL.

In an embodiment, the fourth gate signal supply line GPC4 may be arranged on the same layer as the first gate signal supply line GPC1, the second gate signal supply line GPC2, and the third gate signal supply line GPC3, or be arranged on a different layer.

The thicknesses and arrangement positions of the first gate signal supply line GPC1, the second gate signal supply line GPC2, the third gate signal supply line GPC3, and the fourth gate signal supply line GPC4 and the thicknesses and arrangement positions of the first gate line GWL, the second gate line GIL, the third gate line GEL, the fourth gate line GRL, and the scan lines GSL illustrated in FIG. 8 are just examples, and are not limited to those illustrated in FIG. 8 and may be variously modified.

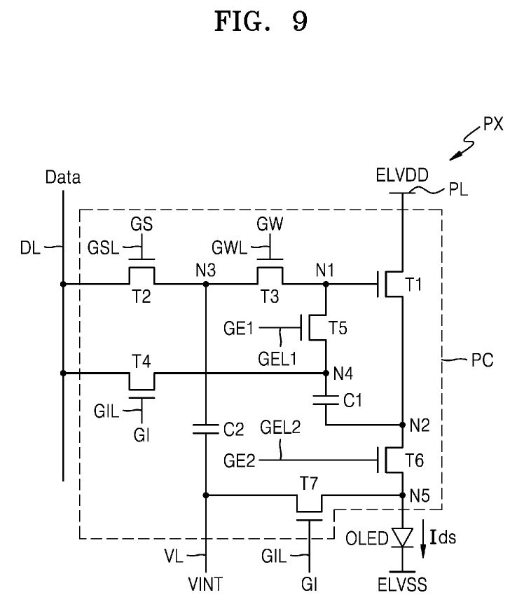

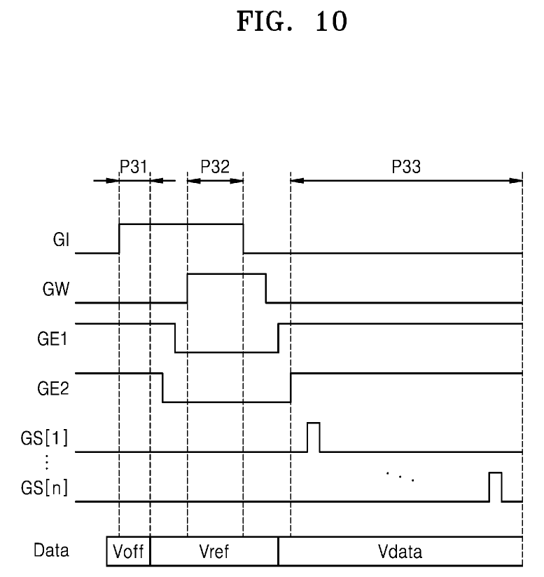

FIG. 9 is an equivalent circuit diagram of a pixel according to an embodiment. FIG. 10 is a schematic view of signals for explaining an operation of the pixel illustrated in FIG. 9.

The pixel PX illustrated in FIG. 9 is different from the pixel illustrated in FIG. 3 in that a gate of the fifth transistor T5 and a gate of the sixth transistor T6 are respectively connected to gate lines different from each other. Hereinafter, the differences from FIG. 3 and FIG. 9 are mainly described, and descriptions of the same construction and operation are omitted.

The fifth transistor T5 may include a gate, a first terminal, and a second terminal, wherein the gate is connected to a third-1 gate line GEL1, the first terminal is connected to the gate of the first transistor T1, and the second terminal is connected to the fourth node N4. The fifth transistor T5 may be turned on or turned off according to a third-1 gate signal GE1 provided to the third-1 gate line GEL1.

The sixth transistor T6 may include a gate, a first terminal, and a second terminal, wherein the gate is connected to a third-2 gate line GEL2, the first terminal is connected to the second terminal of the first transistor T1, and the second terminal is connected to the pixel electrode of the organic light-emitting diode OLED. The sixth transistor T6 may be turned on or turned off according to a third-2 gate signal GE2 provided to the third-2 gate line GEL2.

Referring to FIG. 10, a first gate signal GW may be supplied as a gate-on voltage during a second period P32, and be supplied as a gate-off voltage during a first period P31 and a third period P33. A second gate signal GI may be supplied as a gate-on voltage during the first period P31 and the second period P32, and be supplied as a gate-off voltage during the third period P33. A third-1 gate signal GE1 and a third-2 gate signal GE2 may be supplied as a gate-off voltage during the second period P32, and be supplied as a gate-on voltage during the first period P31 and the third period P33.

During the first period P31, the fourth transistor T4 and the seventh transistor T7 may be turned on by a second gate signal GI of a gate-on voltage, the fifth transistor T5 may be turned on by a third-1 gate signal GE1 of a gate-on voltage, and the sixth transistor T6 may be turned on by a third-2 gate signal GE2 of a gate-on voltage.

The off-voltage Voff supplied to the data line DL may be provided to the fourth node N4 and the first node N1 by the fourth transistor T4 and the fifth transistor T5 that are turned on. Accordingly, the gate of the first transistor T1 may be initialized to the off-voltage Voff.

The initialization voltage VINT may be provided to the pixel electrode of the organic light-emitting diode OLED and the second node N2 by the seventh transistor T7 and the sixth transistor T6 that are turned on. Accordingly, the pixel electrode of the organic light-emitting diode OLED may be initialized to the initialization voltage VINT.

During the second period P32, the third transistor T3 may be turned on according to a first gate signal GW of a gate-on voltage, and the fourth transistor T4 and the seventh transistor T7 may be turned on according to a second gate signal GI of a gate-on voltage.

The data voltage Vdata provided to the third node N3 during the third period P33 of a previous frame, may be provided to the first node N1 by the third transistor T3 that is turned on. A voltage of the second terminal of the first transistor T1 may be a voltage (Vdata-Vth) obtained by subtracting the threshold voltage Vth of the first transistor T1 from the data voltage Vdata. The reference voltage Vref supplied from the data line DL may be provided to the fourth node N4 by the fourth transistor T4 that is turned on. Accordingly, because a voltage difference (Vref-Vdata+Vth) between both terminals of the first capacitor C1 is stored in the first capacitor C1, the threshold voltage Vth of the first transistor T1 may be compensated.

A voltage of the fifth node N5 may maintain the initialization voltage VINT of the first period P31 due to the seventh transistor T7 that is turned on.

During the third period P33, the fifth transistor T5 may be turned on according to a third-1 gate signal GE1 of a gate-on voltage, the sixth transistor T6 may be turned on according to a third-2 gate signal GE2 of a gate-on voltage, and the first transistor T1 may output the driving current Ids determined according to a gate-source voltage Vgs. The driving current Ids (Ids∝ (Vref-Vdata)²) output by the first transistor T1 flows through the organic light-emitting diode OLED through the sixth transistor T6 that is turned on, and the organic light-emitting diode OLED may emit light at a brightness corresponding to the driving current Ids.

In an embodiment, a timing at which a third-1 gate signal GE1 transitions from a gate-off voltage to a gate-on voltage may be faster by a preset time than a timing at which a third-2 gate signal GE2 transitions from a gate-off voltage to a gate-on voltage. In the pixel PX, a gate-source voltage Vgs of the first transistor T1 is defined first by a third-1 gate signal GE1 of a gate-on voltage, and then, the pixel PX may start to emit light according to a third-2 gate signal GE2 of a gate-on voltage and may more stably emit light.

While all the pixels PX emit light during the third period P33, a first scan signal GS[1] to a last n-th scan signal GS[n] of a gate-on voltage is sequentially supplied to the display area DA, and the data voltage Vdata of a next frame may be sequentially written from the pixels PX in a first row to the pixels PX in a last n-th row. The second transistor T2 of the pixel PX to which a scan signal GS of a gate-on voltage is supplied is turned on, the data voltage Vdata of a next frame supplied to the data line DL is provided to the third node N3, and the data voltage Vdata of the next frame may be stored in the second capacitor C2.

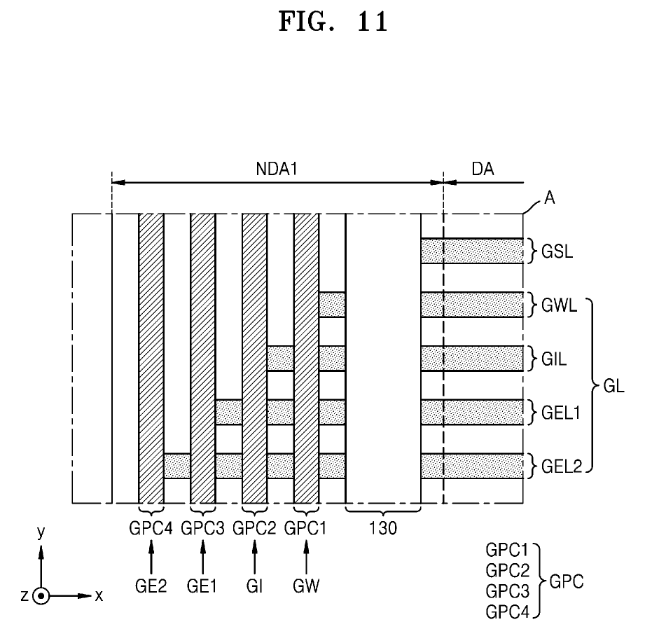

FIG. 11 is an enlarged plan view of a portion of the display device according to an embodiment, illustrating the region A of FIG. 1.

Referring to FIG. 11, in an embodiment, the display device 10 to which the pixel PX illustrated in FIG. 9 is applied may include gate signal supply lines GPC in the non-display area NDA. The gate signal supply lines GPC may include a first gate signal supply line GPC1 supplying a first gate signal GW, a second gate signal supply line GPC2 supplying a second gate signal GI, a third gate signal supply line GPC3 supplying a third-1 gate signal GE1, and a fourth gate signal supply line GPC4 supplying a third-2 gate signal GE2.

The first gate signal supply line GPC1 is connected to the first gate line GWL and may supply a first gate signal GW supplied from the power supply circuit 170 to the first gate line GWL. The second gate signal supply line GPC2 is connected to the second gate line GIL and may supply a second gate signal GI supplied from the power supply circuit 170 to the second gate line GIL. The third gate signal supply line GPC3 is connected to a third-1 gate line GEL1 and may supply a third-1 gate signal GE1 supplied from the power supply circuit 170 to the third-1 gate line GEL1. The fourth gate signal supply line GPC4 is connected to a third-2 gate line GEL2 and may supply a third-2 gate signal GE2 supplied from the power supply circuit 170 to the third-2 gate line GEL2.

In an embodiment, the third gate signal supply line GPC3 and the fourth gate signal supply line GPC4 may be arranged on the same layer as the first gate signal supply line GPC1 and the second gate signal supply line GPC2 or be arranged on a different layer.

The thicknesses and arrangement positions of the first gate signal supply line GPC1, the second gate signal supply line GPC2, the third gate signal supply line GPC3, and the fourth gate signal supply line GPC4 and the thicknesses and arrangement positions of the first gate line GWL, the second gate line GIL, the third-1 gate line GEL1, the third-2 gate line GEL2, and the scan lines GSL illustrated in FIG. 11 are just examples, and are not limited to those illustrated in FIG. 11 and may be variously modified.

The display device 10 to which the pixel PX illustrated in FIGS. 3, 6, and 9 is applied may be implemented without driving circuits for generating first to fourth gate signals GW, GI, GE, GE1, GE2, and GR, and the first to fourth gate signals GW, GI, GE, GE1, GE2, and GR may be supplied as global signals to the pixel PX. Accordingly, because the display device 10 to which the pixel PX illustrated in FIGS. 3, 6, and 9 is applied may be implemented without four driving circuits for respectively generating the first to fourth gate signals GW, GI, GE, GE1, GE2, and GR, the size of the non-display area NDA may be reduced.

Because, in the pixel PX according to embodiments, the first capacitor C1 and the second capacitor C2 do not share a node, the first capacitor C1 and the second capacitor C2 may not share charge. Compared to a pixel in which the first capacitor C1 and the second capacitor C2 share charge by sharing a node, in the pixel PX according to embodiments, there is no data loss, and thus, a range in a data voltage is reduced and power consumption may be reduced.

In the pixel PX according to embodiments, the first transistor T1 may be directly connected to the driving voltage line PL. In a pixel where the first transistor T1 is not directly connected to the driving voltage line PL, and a transistor is provided between the first transistor T1 and the driving voltage line PL, a voltage greater than the first power voltage ELVDD required for driving the pixel should be provided to the driving voltage line PL. In the pixel PX according to embodiments, because the first transistor T1 is directly connected to the driving voltage line PL, the first power voltage ELVDD for driving the pixel may be supplied to the driving voltage line PL.

In the display device 10 to which the pixel PX according to embodiments is applied, the gate signals GW, GI, GR, GE/GE1/GE2 may be used as global signals supplied from conductive lines in the non-display area NDA. Accordingly, because the scan driver 130 supplying scan signals GS is provided in the non-display area NDA, and the display device 10 may be implemented without separate driving circuits for supplying gate signals GW, GI, GR, GE/GE1/GE2, the size of the non-display area NDA is reduced, and thus, a narrow bezel is advantageously implemented.

In the above embodiment, although the plurality of transistors included in the pixel circuit are described as N-channel transistors, embodiments of the present disclosure are not limited thereto. In an embodiment, at least one of the plurality of transistors included in the pixel circuit may be a P-channel transistor. As an example, at least one of switching transistors other than the driving transistor may be a P-channel transistor. A low-level voltage input to a gate of a P-channel transistor may be a gate-on voltage, and a high-level voltage may be defined as a gate-off voltage. The P-channel transistor may be a silicon transistor. The silicon transistor may be a low temperature polysilicon (LTPS) thin-film transistor including a semiconductor layer, but embodiments of the present disclosure are not limited thereto, and the semiconductor layer includes amorphous silicon, polycrystalline silicon, and the like.

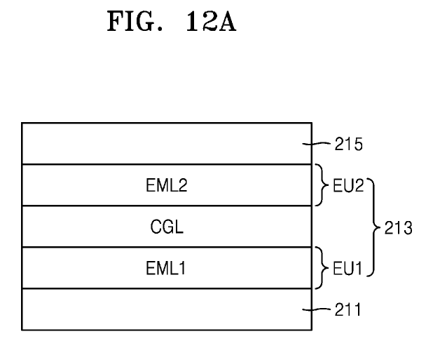

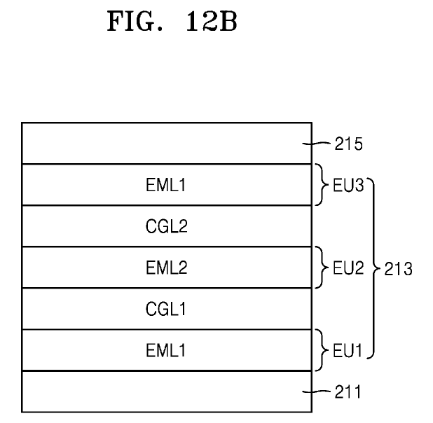

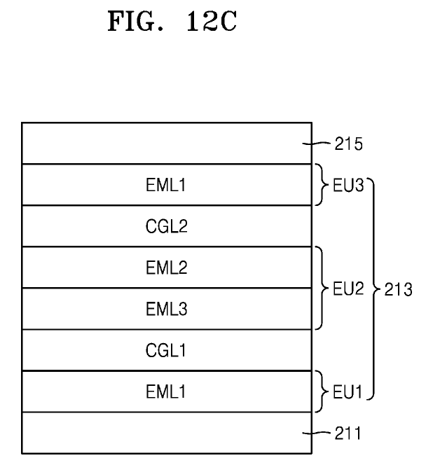

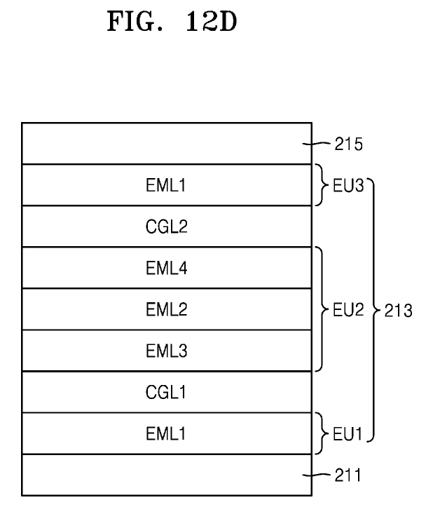

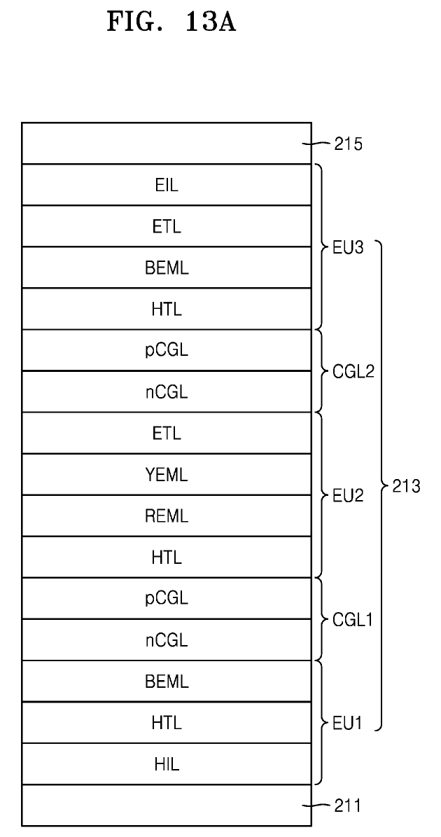

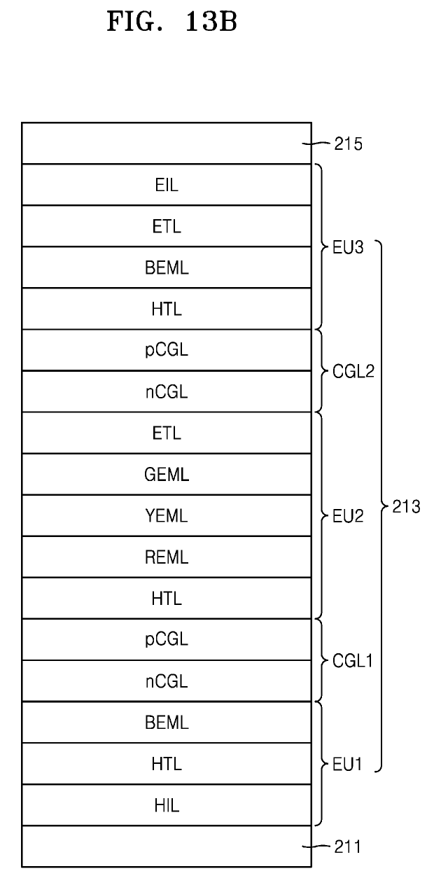

FIGS. 12A to 12D and FIGS. 13A and 13B are cross-sectional views of a structure of a display element according to an embodiment.

The organic light-emitting diode OLED, which is a display element according to an embodiment, may include a pixel electrode 211, an opposite electrode 215, and an intermediate layer 213 between the pixel electrode 211 (a first electrode, e.g., an anode) and the opposite electrode 215 (a second electrode, e.g., a cathode).

The pixel electrode 211 may include a light-transmissive conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. As an example, the pixel electrode 211 may have a three-layered structure of ITO/Ag/ITO.

The opposite electrode 215 may be arranged on the intermediate layer 213. The opposite electrode 215 may include a metal, alloy, electrically conductive compound, or any combination thereof having a low work function. As an example, the opposite electrode 215 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or any combination thereof. The opposite electrode 215 may be a transmissive electrode, a semi-transmissive electrode, or a reflective electrode.

The intermediate layer 213 may include a polymer organic material or a low-molecular weight organic material emitting light having a preset color. In addition to various organic materials, the intermediate layer 213 may further include metal-containing compounds such as, for example, organometallic compounds, inorganic materials such as, for example, quantum dots, and the like.

In an embodiment, the intermediate layer 213 may include one emission layer and a first functional layer and a second functional layer respectively under and on the emission layer. The first functional layer may include, for example, a hole transport layer (HTL), or include an HTL and a hole injection layer (HIL). The second functional layer may include an electron transport layer (ETL) and/or an electron injection layer (EIL). In some embodiments, the first functional layer or the second functional layer may be omitted. The first functional layer and the second functional layer may be integrally formed to correspond to the plurality of organic light-emitting diodes OLED included in the display area DA.

In an embodiment, the intermediate layer 213 may include two or more emitting units and a charge generation layer CGL arranged between the two emitting units, wherein the two or more emitting units are sequentially stacked between the pixel electrode 211 and the opposite electrode 215. In the case where the intermediate layer 213 includes the emitting unit and the charge generation layer, the organic light-emitting diode OLED may be a tandem light-emitting element. The organic light-emitting diode OLED may be configured to improve color purity and a light emission efficiency by having a stack structure of a plurality of emitting units.

One emitting unit may include the emission layer and the first functional layer and the second functional layer respectively under and on the emission layer. The charge generation layer CGL may include a negative charge generation layer and a positive charge generation layer. A light-emission efficiency of the organic light-emitting diode OLED, which is a tandem light-emitting element including a plurality of emission layers, may be enhanced even more by the negative charge generation layer and the positive charge generation layer.

The negative charge generation layer may be an n-type charge generation layer. The negative charge generation layer may be configured to supply electrons. The negative charge generation layer may include a host and a dopant. The host may include an organic material. The dopant may include a metal material. The positive charge generation layer may be a p-type charge generation layer. The positive charge generation layer may be configured to supply holes. The positive charge generation layer may include a host and a dopant. The host may include an organic material. The dopant may include a metal material.

In an embodiment, as illustrated in FIG. 12A, the organic light-emitting diode OLED may include a first emitting unit EU1 and a second emitting unit EU2 that are sequentially stacked, wherein the first emitting unit EU1 includes a first emission layer EML1, and the second emitting unit EU2 includes a second emission layer EML2. The charge generation layer CGL may be arranged between the first emitting unit EU1 and the second emitting unit EU2. As an example, the organic light-emitting diode OLED may include the pixel electrode 211, the first emission layer EML1, the charge generation layer CGL, the second emission layer EML2, and the opposite electrode 215 that are sequentially stacked. The first functional layer and the second functional layer may be arranged under and on the first emission layer EML1. The first functional layer and the second functional layer may be arranged under and on the second emission layer EML2. The first emission layer EML1 may be a blue emission layer, and the second emission layer EML2 may be a yellow emission layer.

In an embodiment, as illustrated in FIG. 12B, the organic light-emitting diode OLED may include a first emitting unit EU1, a second emitting unit EU2, and a third emitting unit EU3 that are sequentially stacked, wherein the first emitting unit EU1 includes the first emission layer EML1, and the second emitting unit EU2 includes the second emission layer EML2. A first charge generation layer CGL1 may be arranged between the first emitting unit EU1 and the second emitting unit EU2, and a second charge generation layer CGL2 may be arranged between the second emitting unit EU2 and the third emitting unit EU3. As an example, the organic light-emitting diode OLED may include the pixel electrode 211, the first emission layer EML1, the first charge generation layer CGL1, the second emission layer EML2, the second charge generation layer CGL2, the first emission layer EML1, and the opposite electrode 215 that are sequentially stacked. The first functional layer and the second functional layer may be arranged under and on the first emission layer EML1. The first functional layer and the second functional layer may be arranged under and on the second emission layer EML2. The first emission layer EML1 may be a blue emission layer, and the second emission layer EML2 may be a yellow emission layer.

In an embodiment, in the organic light-emitting diode OLED, the second emitting unit EU2 may further include a third emission layer EML3 and/or a fourth emission layer EML4 that are in direct contact with the second emission layer EML2 under and/or on the second emission layer EML2 in addition to the second emission layer EML2. Here, direct contact may mean that another layer is not arranged between the second emission layer EML2 and the third emission layer EML3 and/or the second emission layer EML2 and the fourth emission layer EML4. The third emission layer EML3 may be a red emission layer, and the fourth emission layer EML4 may be a green emission layer.

As an example, as illustrated in FIG. 12C, the organic light-emitting diode OLED may include the pixel electrode 211, the first emission layer EML1, the first charge generation layer CGL1, the third emission layer EML3, the second emission layer EML2, the second charge generation layer CGL2, the first emission layer EML1, and the opposite electrode 215 that are sequentially stacked. Alternatively, as illustrated in FIG. 12D, the organic light-emitting diode OLED may include the pixel electrode 211, the first emission layer EML1, the first charge generation layer CGL1, the third emission layer EML3, the second emission layer EML2, the fourth emission layer EML4, the second charge generation layer CGL2, the first emission layer EML1, and the opposite electrode 215 that are sequentially stacked.

FIG. 13A is a cross-sectional view illustrating an example of the organic light-emitting diode of FIG. 12C, and FIG. 13B is a cross-sectional view illustrating an example of the organic light-emitting diode of FIG. 12D.

Referring to FIG. 13A, the organic light-emitting diode OLED may include the first emitting unit EU1, the second emitting unit EU2, and the third emitting unit EU3 that are sequentially stacked. A first charge generation layer CGL1 may be arranged between the first emitting unit EU1 and the second emitting unit EU2, and a second charge generation layer CGL2 may be arranged between the second emitting unit EU2 and the third emitting unit EU3. The first charge generation layer CGL1 and the second charge generation layer CGL2 may respectively include a negative charge generation layer nCGL and a positive charge generation layer pCGL.

The first emitting unit EU1 may include a blue emission layer BEML. The first emitting unit EU1 may further include a hole injection layer HIL and a hole transport layer HTL between the pixel electrode 211 and the blue emission layer BEML. In an embodiment, a p-doped layer may be further arranged between the hole injection layer HIL and the hole transport layer HTL. A p-doped layer may be formed by doping the hole injection layer HIL with p-type dopants. In an embodiment, at least one of a blue light auxiliary layer, an electron blocking layer, and a buffer layer may be further arranged between the blue emission layer BEML and the hole transport layer HTL. The blue light auxiliary layer may be configured to enhance a light emission efficiency of the blue emission layer BEML. The blue light auxiliary layer may be configured to enhance a light emission efficiency of the blue emission layer BEML by adjusting a hole charge balance. The electron blocking layer may prevent injection of electrons into the hole transport layer (HTL). The buffer layer may be configured to compensate for a resonance distance depending on the wavelength of light emitted from the emission layer.

The second emitting unit EU2 may include a yellow emission layer YEML and a red emission layer REML under the yellow emission layer YEML that is in direct contact with the yellow emission layer YEML. The second emitting unit EU2 may further include a hole transport layer HTL between the red emission layer REML and the positive charge generation layer pCGL of the first charge generation layer CGL1 and further include an electron transport layer ETL between the yellow emission layer YEML and a negative charge generation layer nCGL of the second charge generation layer CGL2.

The third emitting unit EU3 may include a blue emission layer BEML. The third emitting unit EU3 may further include a hole transport layer HTL between the blue emission layer BEML and the positive charge generation layer pCGL of the second charge generation layer CGL2. The third emitting unit EU3 may further include an electron transport layer ETL and an electron injection layer EIL between the blue emission layer BEML and the opposite electrode 215. The electron transport layer ETL may include a single layer or a multi-layer. In an embodiment, at least one of a blue light auxiliary layer, an electron blocking layer, and a buffer layer may be further arranged between the blue emission layer BEML and the hole transport layer HTL. At least one of a hole blocking layer and a buffer layer may be further arranged between the blue emission layer BEML and the electron transport layer ETL. The hole blocking layer may prevent injection of holes into the electron transport layer (ETL).

The organic light-emitting diode OLED illustrated in FIG. 13B is different from the organic light-emitting diode OLED illustrated in FIG. 13A in the stack structure of the second emitting unit EU2, and other constructions are the same. Referring to FIG. 13B, the second emitting unit EU2 may include the yellow emission layer YEML, the red emission layer REML under the yellow emission layer YEML and being in direct contact with the yellow emission layer YEML, and the green emission layer GEML on the yellow emission layer YEML and being in direct contact with the yellow emission layer YEML. The second emitting unit EU2 may further include a hole transport layer HTL between the red emission layer REML and the positive charge generation layer pCGL of the first charge generation layer CGL1 and further include an electron transport layer ETL between the green emission layer GEML and a negative charge generation layer nCGL of the second charge generation layer CGL2.

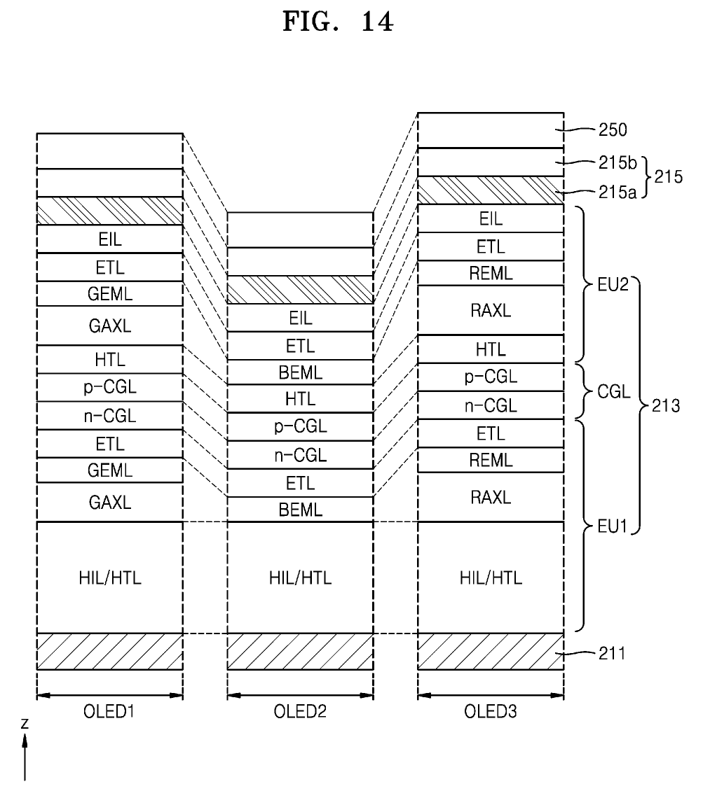

FIG. 14 is a schematic cross-sectional view of a structure of a display element according to an embodiment.

Referring to FIG. 14, the display element according to an embodiment may be an organic light-emitting diode. Each of a first organic light-emitting diode OLED1 included in a first pixel, a second organic light-emitting diode OLED2 included in a second pixel, and a third organic light-emitting diode OLED3 included in a third pixel, may include the pixel electrode 211, the opposite electrode 215, and the intermediate layer 213 between the pixel electrode 211 and the opposite electrode 215. The pixel electrodes 211 may be respectively and independently provided to the first organic light-emitting diode OLED1, the second organic light-emitting diode OLED2, and the third organic light-emitting diode OLED3. The opposite electrode 215 may include a first conductive layer 215a and a second conductive layer 215b.

The first conductive layer 215a may include silver (Ag) or a silver alloy. The silver alloy may be a silver magnesium alloy (AgMg), a silver ytterbium alloy (AgYb), a silver palladium copper alloy (AgPdCu), or a silver lithium alloy (AgLi) with a silver content of 90% or more. The first conductive layer 215a may be formed through a thermal deposition process.

The second conductive layer 215b may include a transparent conductive oxide. The transparent conductive oxide may include indium tin oxide (ITO), indium zinc oxide (IZO), zinc oxide (ZnO), indium oxide (In₂O₃), indium gallium oxide (IGO), indium gallium zinc oxide (IGZO), gallium zinc oxide (GZO), or aluminum zinc oxide (AZO). The second conductive layer 215b may be formed through a sputtering process. The second conductive layer 215b may be continuously and commonly provided to the first organic light-emitting diode OLED1, the second organic light-emitting diode OLED2, and the third organic light-emitting diode OLED3.

The intermediate layer 213 of the first organic light-emitting diode OLED1, the second organic light-emitting diode OLED2, and the third organic light-emitting diode OLED3 may include the first emitting unit EU1, the second emitting unit EU2, and the charge generation layer CGL between the first emitting unit EU1 and the second emitting unit EU2.

The first emitting unit EU1 of the first organic light-emitting diode OLED1 may include a hole transport layer HTL/hole injection layer HIL, a green auxiliary layer GAXL, a green emission layer GEML, and an electron transport layer ETL that are sequentially stacked on the pixel electrode 211. The first emitting unit EU1 of the second organic light-emitting diode OLED2 may include a hole transport layer HTL/hole injection layer HIL, a blue emission layer BEML, and an electron transport layer ETL that are sequentially stacked on the pixel electrode 211. The first emitting unit EU1 of the third organic light-emitting diode OLED3 may include a hole transport layer HTL/hole injection layer HIL, a red auxiliary layer RAXL, a red emission layer REML, and an electron transport layer ETL that are sequentially stacked on the pixel electrode 211. The red auxiliary layer RAXL and the green auxiliary layer GAXL are added layers to match a resonance distance and may include resonance auxiliary materials. In an embodiment, the red auxiliary layer RAXL and the green auxiliary layer GAXL may include the same material as the hole transport layer HTL. In some embodiments, the green auxiliary layer GAXL may be omitted.

The second emitting unit EU2 of the first organic light-emitting diode OLED1 may include a hole transport layer HTL, a green auxiliary layer GAXL, a green emission layer GEML, an electron transport layer ETL, and an electron injection layer EIL that are sequentially stacked on a charge generation layer CGL. The second emitting unit EU2 of the second organic light-emitting diode OLED2 may include a hole transport layer HTL, a blue emission layer BEML, an electron transport layer ETL, and an electron injection layer EIL that are sequentially stacked on a charge generation layer CGL. The second emitting unit EU2 of the third organic light-emitting diode OLED3 may include a hole transport layer HTL, a red auxiliary layer RAXL, a red emission layer REML, an electron transport layer ETL, and an electron injection layer EIL that are sequentially stacked on a charge generation layer CGL.

The green emission layer GEML and the green auxiliary layer GAXL may be patterned to correspond to the first organic light-emitting diode OLED1. The blue emission layer BEML may be patterned to correspond to the second organic light-emitting diode OLED2. The red emission layer REML and the red auxiliary layer RAXL may be patterned to correspond to the third organic light-emitting diode OLED3.

The thickness of each of the green emission layer GEML, the blue emission layer BEML, and the red emission layer REML may be determined according to a resonance distance. In embodiments, a hole transport layer HTL, a hole transport layer/hole injection layer HTL/HIL, an electronic transport layer ETL, an electron injection layer EIL, and a charge generation layer CGL may be deposited on the entire surface of the display area DA. At least one of a hole transport layer HTL, a hole transport layer/hole injection layer HTL/HIL, an electronic transport layer ETL, an electron injection layer EIL, and a charge generation layer CGL may be separated by a separator and independently provided to each of the first organic light-emitting diode OLED1, the second organic light-emitting diode OLED2, and the third organic light-emitting diode OLED3. In an embodiment, the first conductive layer 215a may be separated by a separator and independently provided to each of the first organic light-emitting diode OLED1, the second organic light-emitting diode OLED2, and the third organic light-emitting diode OLED3. In another embodiment, the first conductive layer 215a may be continuously and commonly provided to the first organic light-emitting diode OLED1, the second organic light-emitting diode OLED2, and the third organic light-emitting diode OLED3.

A capping layer 250 may be arranged on the opposite electrode 215. The capping layer 250 may be configured to improve a light-emission efficiency based on a constructive interference principle. The capping layer 250 may include a material having a refractive index (at about 589nm) of about 1.6. The capping layer 250 may be an organic capping layer including an organic material, an inorganic capping layer including an inorganic material, or a composite capping layer including an organic material and an inorganic material. In an embodiment, the capping layer 250 may include lithium fluoride (LiF).

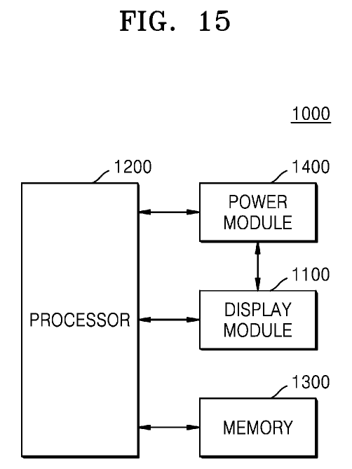

FIG. 15 is a block diagram of an electronic device 1000 according to an embodiment.

Referring to FIG. 15, the electronic device 1000 according to an embodiment may include a display module 1100, a processor 1200, a memory 1300, and a power module 1400.

The electronic device 1000 may output various information through the display module 1100 within an operating system.

The processor 1200 may include at least one of a central processing unit (CPU), an application processor (AP), a graphic processing unit (GPU), a communication processor (CP), an image signal processor (ISP), and a controller. In an embodiment, the processor 1200 may be divided into two or more in a functional or structural viewpoint. As an example, the processor may include a main processor of a first driving chip form including a central processing unit, and an auxiliary processor of a second driving chip including a controller receiving image signals from the main processor and processing image signals to match an interface specification of the display module 1100.

The memory 1300 may include at least one of a non-volatile memory and a volatile memory. Data information supportive of operations of the processor 1200 or the display module 1100 may be stored in the memory 1300. In an example in which the processor 1200 executes an application stored in the memory 1300, an image data signal and/or an input control signal is provided to the display module 1100, and the display module 1100 may process the provided signal and output image information through a display screen.

The power module 1400 may include a power supply module such as, for example, a power adapter or a battery unit, and a power converting module converting power supplied by the power supply module and generating power for operations of the electronic device 1000. Power conversion performed by the power converting module may include DC-DC conversion, AC-DC conversion, and DC-AC conversion and is not limited thereto.

At least one of elements of the electronic device 1000 may be included within the display device according to the embodiments. In some aspects, some of individual modules functionally included in one module may be included in the display device, and other some may be included in the electronic device 1000 separately from the display device. As an example, the display device may include the display module 1100 and the auxiliary processor of the processor 1200, and the main processor of the processor, the memory 1300, and the power module 1400 may be provided in a form of different device within the electronic device 1000 other than the display device. As another example, the power module 1400 may be prepared within the display device, may supply power to the processor 1200 and the memory 1300 provided within the electronic device 1000 other than the display device, and is not limited to the above example.

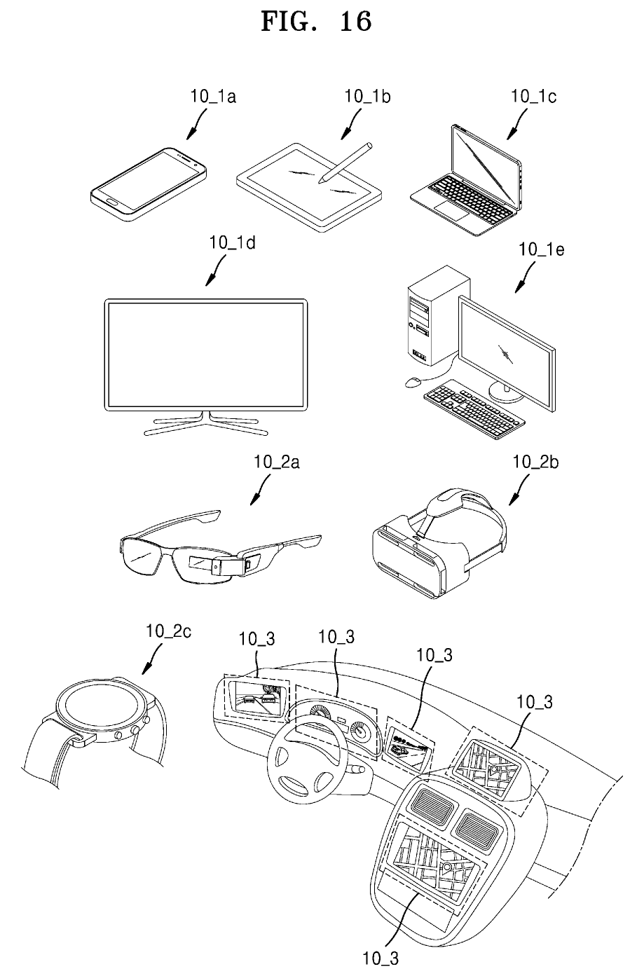

FIG. 16 is a schematic view of electronic devices according to various embodiments.

The display device according to embodiments is a device displaying moving images or still images and is applicable to various electronic devices. Referring to FIG. 16, various electronic device to which the display device according to embodiments are applied may include not only an electronic device for displaying images, such as, for example, a smartphone 10_1a, a tablet personal computer (PC) 10_1b, a laptop computer 10_1c, a TV 10_1d, a desk monitor 10_1e, and the like, but also a wearable electronic device including a display module, such as, for example, a smart-glasses 10_2a, a head mount display 10_2b, a smartwatch 10_2c, and the like, and a vehicle electronic device 10_3 including a display module, such as, for example, an instrument board of an automobile, a center fascia, a center information display (CID) arranged on a dashboard, a room mirror display, and the like. The electronic device 1000 according to embodiments is not limited to the above-described devices.

The electronic device of FIG. 16 may include the elements illustrated in FIG. 15. As an example, the smartphone 10_1a may include the display module 1100, the processor 1200, the memory 1300, and the power module 1400 illustrated in FIG. 15. The smartphone 10_1a may further include a communication module and a battery device. Power provided by the battery device may be converted through the power module 1400 and provided to the processor 1200, the memory 1300, and the display module 1100. In an embodiment, the display device applied to the smartphone 10_1a may include the display module 1100 and further include the power module 1400. Although the processor 1200 and the memory 1300 may be provided in a form of a chip mounted on a motherboard, which is an external device, embodiments of the present disclosure are not limited thereto.

According to embodiments, a high-resolution display device may be provided. However, the scope of the disclosure is not limited by this effect.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A pixel comprising:
a first transistor comprising a gate, a first terminal connected to a driving voltage line, and a second terminal;
a second transistor connected to a data line and comprising a gate connected to a scan line;
a third transistor connected to the second transistor and a first node to which the gate of the first transistor is connected, wherein the third transistor comprises a gate connected to a first gate line;
a fourth transistor connected to the data line and a second node and comprising a gate connected to a second gate line;
a fifth transistor connected to the first node and the second node and comprising a gate connected to a third gate line;
a sixth transistor connected to a third node to which the second terminal of the first transistor is connected and a light-emitting element, wherein the sixth transistor comprises a gate connected to a fourth gate line;
a seventh transistor connected to the sixth transistor and an initialization voltage line and comprising a gate connected to a fifth gate line;
a first capacitor connected to the second node and the third node; and
a second capacitor connected to a fourth node to which the second transistor and the third transistor are connected and the initialization voltage line.

2. The pixel of claim 1, wherein:
a first terminal of the seventh transistor is connected to a fifth node, and a second terminal of the seventh transistor is connected to the initialization voltage line, wherein the sixth transistor and a pixel electrode of the light-emitting element are connected to the fifth node,
a first gate signal is input to the first gate line,
a second gate signal is input to the second gate line and the fifth gate line, and
a third gate signal is input to the third gate line and the fourth gate line.

3. The pixel of claim 2, wherein, during a first period of a frame:
the first gate signal and a scan signal which is input via the scan line have a gate-off voltage,
the second gate signal and the third gate signal have a gate-on voltage,
the gate of the first transistor is initialized to a first voltage which is input to the data line, and
the pixel electrode of the light-emitting element is initialized to an initialization voltage which is input to the initialization voltage line.

4. The pixel of claim 3, wherein, during a second period subsequent to the first period of the frame:
the first gate signal and the second gate signal have a gate-on voltage,
the scan signal and the third gate signal have a gate-off voltage,
a data voltage stored in the second capacitor is provided to the gate of the first transistor, and
a second voltage which is input to the data line is provided to the second node.

5. The pixel of claim 4, wherein, during a third period subsequent to the second period of the frame:
the first gate signal and the second gate signal have a gate-off voltage,
the third gate signal has a gate-on voltage, and
the light-emitting element emits light corresponding to a data voltage provided to the gate of the first transistor,
wherein during a portion of the third period, the scan signal has a gate-on voltage, and a data voltage which is associated with a next frame and input to the data line is provided to the fourth node.

6. The pixel of claim 1, wherein:
a first terminal of the seventh transistor is connected to the third node, and a second terminal of the seventh transistor is connected to the initialization voltage line,
a first gate signal is input to the first gate line,
a second gate signal is input to the fifth gate line,
a third gate signal is input to the third gate line and the fourth gate line, and
a fourth gate signal is input to the second gate line.

7. The pixel of claim 6, wherein during a first period of a frame:
the first gate signal and a scan signal which is input via the scan line have a gate-off voltage,
the second gate signal, the third gate signal, and the fourth gate signal have a gate-on voltage,
the gate of the first transistor is initialized to a first voltage which is input to the data line, and
a pixel electrode of the light-emitting element is initialized to an initialization voltage which is input to the initialization voltage line.

8. The pixel of claim 7, wherein, during a second period subsequent to the first period of the frame:
the first gate signal and the fourth gate signal have a gate-on voltage,
the scan signal, the second gate signal, and the third gate signal have a gate-off voltage,
a data voltage stored in the second capacitor is provided to the gate of the first transistor, and
a second voltage which is input to the data line is provided to the second node.

9. The pixel of claim 8, wherein, during a third period subsequent to the second period of the frame:
the first gate signal, the second gate signal, and the fourth gate signal have a gate-off voltage,
the third gate signal has a gate-on voltage, and
the light-emitting element emits light corresponding to a data voltage provided to the gate of the first transistor,
wherein during a portion of the third period, the scan signal has a gate-on voltage, and a data voltage which is associated with a next frame and input to the data line is provided to the fourth node.

10. The pixel of claim 1, wherein:
a first terminal of the seventh transistor is connected to a fifth node, and a second terminal of the seventh transistor is connected to the initialization voltage line, wherein the sixth transistor and a pixel electrode of the light-emitting element are connected to the fifth node,
a first gate signal is input to the first gate line,
a second gate signal is input to the second gate line and the fifth gate line,
a third gate signal is input to the third gate line, and
a fourth gate signal is input to the fourth gate line.

11. The pixel of claim 10, wherein, during a first period of a frame:
the first gate signal and a scan signal which is input via the scan line have a gate-off voltage,
the second gate signal, the third gate signal, and the fourth gate signal have a gate-on voltage,
the gate of the first transistor is initialized to a first voltage which is input to the data line, and
a pixel electrode of the light-emitting element is initialized to an initialization voltage which is input to the initialization voltage line.

12. The pixel of claim 11, wherein, during a second period subsequent to the first period of the frame:
the first gate signal and the second gate signal have a gate-on voltage,
the scan signal, the third gate signal, and the fourth gate signal have a gate-off voltage,
a data voltage stored in the second capacitor is provided to the gate of the first transistor, and
a second voltage which is input to the data line is provided to the second node.

13. The pixel of claim 12, wherein:, during a third period subsequent to the second period of the frame:
the first gate signal and the second gate signal have a gate-off voltage,
the third gate signal and the fourth gate signal have a gate-on voltage, and
the light-emitting element emits light corresponding to a data voltage provided to the gate of the first transistor,
wherein during a portion of the third period, the scan signal has a gate-on voltage, and a data voltage which is associated with a next frame and input to the data line is provided to the fourth node.

14. A display device comprising:
a controller which receives an on-operation signal from a processor and outputs a control signal based on the on-operation signal;
a driving circuit which receives the control signal and comprises a plurality of stages that sequentially output scan signals;
at least one gate signal supply line which receives the control signal and outputs at least one gate signal; and
a plurality of pixels,
wherein each of the plurality of pixels comprises:
a first transistor comprising a gate, a first terminal connected to a driving voltage line, and a second terminal;
a second transistor connected to a data line and comprising a gate connected to a scan line to which a scan signal of the scan signals output by the driving circuit is input;
a third transistor connected to the second transistor and a first node to which the gate of the first transistor is connected, wherein the third transistor comprises a gate connected to a first gate line;
a fourth transistor connected to the data line and a second node and comprising a gate connected to a second gate line;
a fifth transistor connected to the first node and the second node and comprising a gate connected to a third gate line;
a sixth transistor connected to a third node to which the second terminal of the first transistor is connected and a light-emitting element, wherein the sixth transistor comprises a gate connected to a fourth gate line;
a seventh transistor connected to the sixth transistor and an initialization voltage line and comprising a gate connected to a fifth gate line;
a first capacitor connected to the second node and the third node; and
a second capacitor connected to a fourth node to which the second transistor and the third transistor are connected and the initialization voltage line, and
wherein the at least one gate signal supply line supplies a gate signal to each of the first gate line, the second gate line, the third gate line, the fourth gate line, and the fifth gate line.

15. The display device of claim 14, wherein:
a first terminal of the seventh transistor is connected to a fifth node, and a second terminal of the seventh transistor is connected to the initialization voltage line, wherein the sixth transistor and a pixel electrode of the light-emitting element are connected to the fifth node,
a first gate signal is input to the first gate line,
a second gate signal is input to the second gate line and the fifth gate line, and
a third gate signal is input to the third gate line and the fourth gate line.

16. The display device of claim 15, wherein:
during a first period of a frame:
the first gate signal and the scan signal have a gate-off voltage,
the second gate signal and the third gate signal have a gate-on voltage,
the gate of the first transistor is initialized to a first voltage which is input to the data line, and
a pixel electrode of the light-emitting element is initialized to an initialization voltage which is input to the initialization voltage line,
during a second period subsequent to the first period of the frame:
the first gate signal and the second gate signal have a gate-on voltage,
the scan signal and the third gate signal have a gate-off voltage,
a data voltage stored in the second capacitor is provided to the gate of the first transistor, and
a second voltage which is input to the data line is provided to the second node, and
during a third period subsequent to the second period of the frame:
the first gate signal and the second gate signal have a gate-off voltage,
the third gate signal has a gate-on voltage, and
the light-emitting element emits light at brightness corresponding to the data voltage provided to the gate of the first transistor,
wherein during a portion of the third period, the scan signal has a gate-on voltage, and a data voltage which is associated with a next frame and input to the data line is provided to the fourth node.

17. The display device of claim 14, wherein:
a first terminal of the seventh transistor is connected to the third node, and a second terminal of the seventh transistor is connected to the initialization voltage line,
a first gate signal is input to the first gate line,
a second gate signal is input to the fifth gate line,
a third gate signal is input to the third gate line and the fourth gate line, and
a fourth gate signal is input to the second gate line.

18. The display device of claim 17, wherein:
during a first period of a frame,
the first gate signal and the scan signal have a gate-off voltage,
the second gate signal, the third gate signal, and the fourth gate signal have a gate-on voltage,
the gate of the first transistor is initialized to a first voltage which is input to the data line, and
a pixel electrode of the light-emitting element is initialized to an initialization voltage which is input to the initialization voltage line,
during a second period subsequent to the first period of the frame:
the first gate signal and the fourth gate signal have a gate-on voltage,
the scan signal, the second gate signal, and the third gate signal have a gate-off voltage,
a data voltage stored in the second capacitor is provided to the gate of the first transistor, and
a second voltage which is input to the data line is provided to the second node, and
during a third period subsequent to the second period of the frame:
the first gate signal, the second gate signal, and the fourth gate signal have a gate-off voltage,
the third gate signal has a gate-on voltage, and
the light-emitting element emits light at brightness corresponding to the data voltage provided to the gate of the first transistor,
wherein during a portion of the third period, the scan signal has a gate-on voltage, and a data voltage which is associated with a next frame and input to the data line is provided to the fourth node.

19. The display device of claim 14, wherein:
a first terminal of the seventh transistor is connected to a fifth node, and a second terminal of the seventh transistor is connected to the initialization voltage line, wherein the sixth transistor and a pixel electrode of the light-emitting element are connected to the fifth node,
a first gate signal is input to the first gate line,
a second gate signal is input to the second gate line and the fifth gate line,
a third gate signal is input to the third gate line, and
a fourth gate signal is input to the fourth gate line.

20. The display device of claim 19, wherein:
during a first period of a frame:
the first gate signal and the scan signal have a gate-off voltage,
the second gate signal, the third gate signal, and the fourth gate signal have a gate-on voltage,
the gate of the first transistor is initialized to a first voltage which is input to the data line, and
a pixel electrode of the light-emitting element is initialized to an initialization voltage which is input to the initialization voltage line,
during a second period subsequent to the first period of the frame:
the first gate signal and the second gate signal have a gate-on voltage,
the scan signal, the third gate signal, and the fourth gate signal have a gate-off voltage,
a data voltage stored in the second capacitor is provided to the gate of the first transistor, and
a second voltage which is input to the data line is provided to the second node, and
during a third period subsequent to the second period of the frame:
the first gate signal and the second gate signal have a gate-off voltage,
the third gate signal and the fourth gate signal have a gate-on voltage, and
the light-emitting element emits light at brightness corresponding to the data voltage provided to the gate of the first transistor,
wherein during a portion of the third period, the scan signal has a gate-on voltage, and a data voltage which is associated with a next frame and input to the data line is provided to the fourth node.

21. An electronic device comprising:
a display device comprising:
a controller which receives an on-operation signal from a processor and outputs a control signal based on the on-operation signal;
a driving circuit which receives the control signal and comprises a plurality of stages that sequentially output scan signals;
at least one gate signal supply line which receives the control signal and outputs at least one gate signal; and
a plurality of pixels,
wherein each of the plurality of pixels comprises:
a first transistor comprising a gate, a first terminal connected to a driving voltage line, and a second terminal;
a second transistor connected to a data line and comprising a gate connected to a scan line to which a scan signal of the scan signals output by the driving circuit is input;
a third transistor connected to the second transistor and a first node to which the gate of the first transistor is connected, wherein the third transistor comprises a gate connected to a first gate line;
a fourth transistor connected to the data line and a second node and comprising a gate connected to a second gate line;
a fifth transistor connected to the first node and the second node and comprising a gate connected to a third gate line;
a sixth transistor connected to a third node to which the second terminal of the first transistor is connected and a light-emitting element, wherein the sixth transistor comprises a gate connected to a fourth gate line;
a seventh transistor connected to the sixth transistor and an initialization voltage line and comprising a gate connected to a fifth gate line;
a first capacitor connected to the second node and the third node; and
a second capacitor connected to a fourth node to which the second transistor and the third transistor are connected and the initialization voltage line, and
wherein the at least one gate signal supply line supplies a gate signal to each of the first gate line, the second gate line, the third gate line, the fourth gate line, and the fifth gate line.
